(19) United States
(12) Patent Application Publication
(10) Pub. No.: US 2018/0105952 A1
(43) Pub. Date: Apr. 19, 2018

(54) METHOD FOR CONTROLLING CRYSTAL PLANE OF POLYCRYSTALLINE METAL AND METAL-CARBON MATERIAL COMPOSITE INCLUDING METAL WHERE CRYSTAL PLANE IS CONTROLLED BY USING THE SAME

(71) Applicant: KOREA INSTITUTE OF SCIENCE AND TECHNOLOGY, Seoul (KR)

(72) Inventors: Han Ik JO, Jeollabuk-do (KR); Sung Ho LEE, Jeollabuk-do (KR); Su Young SON, Jeollabuk-do (KR); Hae Na JO, Jeollabuk-do (KR); Kyung-ae OH, Jeollabuk-do (KR); Tae-Wook KIM, Jeollabuk-do (KR); Dong Su LEE, Jeollabuk-do (KR)

(21) Appl. No.: 15/784,188

(22) Filed: Oct. 16, 2017

(30) Foreign Application Priority Data
Oct. 19, 2016 (KR) 10-2016-0135871

(51) Int. Cl. C30B 28/02; C30B 29/02; B05D 1/18; B05D 3/02; B05D 7/14; B05D 7/20

(52) U.S. Cl. CPC C30B 28/02; C30B 29/02; B05D 7/20; B05D 3/0254; B05D 7/14; B05D 1/18

(57) ABSTRACT

The growth of a specific crystal plane of a polycrystalline metal is induced or suppressed by forming a carbon material on the surface of the polycrystalline metal, and accordingly, the ratio of the crystal plane may be controlled, particularly, the crystal plane may be controlled so as for the polycrystalline metal to be similar to a single crystalline metal. Accordingly, a metal-carbon material composite where a crystal plane is controlled may be mass-produced at low costs through a continuous process.

### CROSS-REFERENCE TO RELATED APPLICATION

This application claims the priority of Korean Patent Application No. 10-2016-0135871, filed on Oct. 19, 2016, and all the benefits accruing therefrom under 35 U.S.C. § 119, the contents of which in its entirety are herein incorporated by reference.

### BACKGROUND

### 1. Field

The present specification relates to a method for controlling a crystal plane of a polycrystalline metal, and a metal-carbon material composite including a metal where a crystal plane is controlled by using the same.

### 2. Description of the Related Art

A metal single crystal has a periodically arranged atomic structure. A polycrystalline metal instead of the single crystal may also partially have a periodic atomic arrangement, but a region having the periodic arrangement is very small. That is, the single crystal consists only of one crystal plane (crystal grain), but the polycrystal is formed by aggregation of a plurality of single crystals having different crystal planes (crystal grains). The structural difference between single crystals and polycrystals governs properties of a material. As described above, the polycrystal consists of multiple crystal planes, and typically, each region having a periodic atomic arrangement in a material refers to a crystal plane or crystal grain, and a boundary, which divides each crystal grain, refers to a crystal grain boundary (see FIG. 28).

However, the crystal grain boundary in the polycrystal is considered as a defect in a crystal structure, and thus becomes a factor negatively affecting physical properties of a material, such as electrical conductivity, heat conductivity, decrease in strength, and acceleration of corrosion rate. Therefore, in order to secure excellent physical properties, a form of single crystals is needed, but a method for growing single crystals is trickier than a method for growing polycrystals as described below, and has a problem in that the amount of single crystals produced is relatively small and preparation costs are high.

A representative method for preparing a single crystalline metal is a Czochralski method. The Czochralski method is a method for growing a single crystalline metal by melting a polycrystalline metal, and then slowly lifting the molten metal upward by bringing a seed crystal into contact with the surface of the metal.

That is, for example, in order to obtain a single crystalline copper wire, the atmosphere in a vessel is made to be in a vacuum state, and the temperature is increased in a state where the external air is blocked from entering into the vessel by filling the vessel with a high-purity argon gas at a pressure slightly higher than the atmospheric pressure. Subsequently, when the temperature approaches a temperature of 1,084° C., which is a melting point of copper, polycrystalline copper begins to slowly melt. When the aforementioned temperature is constantly maintained, the crystalline copper is lifted at a constantly increasing rate and rotation rate by bringing a copper seed crystal into contact with the surface of the molten copper solution. After the polycrystalline copper is grown to a predetermined size or more from the seed crystal, a single crystalline copper wire may be obtained by slowly cooling the polycrystalline copper to room temperature (Non-Patent Document 1).

However, for the methods for preparing a single crystalline metal, the preparation costs thereof are high, and it is difficult to mass-produce the single crystalline metal. In contrast, characteristics of a polycrystalline metal are poorer than those of a single crystalline metal, but the polycrystalline metal is used for various purposes because preparation costs are relatively low and the polycrystalline metal is advantageous in mass production.

### REFERENCES OF THE RELATED ART

### Non-Patent Documents

(Non-Patent Document 1) Non-Patent Document 1: Korean J. Crystallography, 16(2), 141, 2005

### SUMMARY

In an aspect, the present disclosure is directed to providing a method for controlling a crystal plane of a polycrystalline metal, which is capable of forming a carbon material on a surface of the polycrystalline metal, inducing or suppressing growth of a specific crystal plane of the polycrystalline metal, and accordingly controlling the crystal plane, particularly the crystal plane so as to be similar to a crystal plane of a single crystalline metal, and a metal-carbon material composite including a metal where a crystal plane is controlled by using the same.

In another aspect, the present disclosure is directed to providing a method for controlling a crystal plane of a polycrystalline metal, which can mass-produce a metal-carbon material composite where the crystal plane is controlled as described above at low costs through a continuous process, and a metal-carbon material composite including a metal where a crystal plane is controlled by using the same.

In still another aspect, the present disclosure is provided to providing a metal-carbon material composite including a metal where a crystal plane is controlled, the metal-carbon material composite being flexible and having excellent electrical conductivity and mechanical properties.

In yet another aspect, the present disclosure is also directed to providing a metal-carbon material composite including a metal where a crystal plane is controlled, in which the carbon material and the metal are bonded to each other through a strong interaction between the carbon material and the metal.

In an exemplary embodiment, the present disclosure provides a metal-carbon material composite where a carbon material is formed on a surface of a polycrystalline metal, in which the carbon material is formed through a heat treatment of a polymer on the surface of the metal, growth of a specific crystal plane of the polycrystalline metal is promoted or suppressed by forming the carbon material, so that a ratio of the crystal plane of the polycrystalline metal is changed differently from a ratio of the crystal plane of the polycrystalline metal prior to the heat treatment.

In another exemplary embodiment, the present disclosure provides a method for controlling a crystal plane of a polycrystalline metal, in which a carbonization material is formed on a surface of the polycrystalline metal by performing a heat treatment after providing a polymer on the surface of the polycrystalline metal, and growth of a specific crystal plane of the polycrystalline metal is promoted or suppressed, so that a ratio of the crystal plane of the polycrystalline metal is changed differently from a ratio of the crystal plane of the polycrystalline metal prior to the heat treatment.

According to exemplary embodiments of the present disclosure, it is possible to form a carbon material on a surface of a polycrystalline metal and simultaneously induce or suppress growth of a specific crystal plane of the polycrystalline metal through a simple procedure in which a polymer thin film is coated on the surface of the polycrystalline metal and a heat treatment is performed. Accordingly, there may be present one or more of the following effects.

First, it is possible to mass-produce a single crystal-like metal which has characteristics similar to those of a sing crystalline metal at low costs through a continuous process by using a polycrystalline metal.

Further, growth of a specific crystal plane of a polycrystalline metal may be easily induced and suppressed by adjusting one or more of coating conditions such as a concentration of a polymer and carbonization conditions.

In addition, it is possible to easily prepare a metal-carbon material composite, which is finally flexible and has excellent electrical conductivity and mechanical properties. Since the corresponding metal-carbon material composite is in the form of hybrid, separation and purification processes of the carbon material and the metal need not be performed. The metal-carbon material composite may be applied to various fields such as wired/wireless communication, electrode material, and electromagnetic wave shielding material because the carbon metal and the metal are bonded to each other through a strong interaction between the carbon material and the metal.

### BRIEF DESCRIPTION OF THE DRAWINGS

FIGS. 1A and 1B are schematic views showing a continuous procedure of controlling a crystal plane of a metal according to an exemplary embodiment of the present disclosure.

FIG. 1A is a schematic view showing an example of forming a composite wire of graphene and copper by forming graphene as a carbon material in a metal wire.

FIG. 1B is a schematic view showing an example of forming a composite of graphene and a metal film by forming a polymer film on a metal foil and carbonizing the polymer film.

FIG. 2 is an XRD graph of a graphene/copper composite prepared according to the carbonization process temperature in Example 1 of Experiment 1 of the present disclosure and coppers in the Comparative Examples. In FIG. 2, an incident angle 2 theta (unit: degree) of X ray is marked on the X-axis, and the intensities (no unit) of pure polycrystalline copper (PCW) in Comparative Example 1, a graphene/copper composite for each temperature (GCW carbonization temperature) of the carbonization process in Example 1, heat-treated pure polycrystalline copper (ACW) in Comparative Example 2, and pure single crystalline copper (SCW) in Comparative Example 3 are marked on the Y-axis.

FIG. 3 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process temperature in Example 1 of Experiment 1 of the present disclosure and coppers in the Comparative Examples. In FIG. 3, Comparative Example 1 (PCW), Example 1 (GCW carbonization temperature), Comparative Example 2 (ACW), and Comparative Example 3 (SCW) are each marked on the X-axis, and the intensity ratios (no unit) are marked on the Y-axis.

FIG. 4 is an indication of a change in intensity of each crystal plane of copper according to the carbonization process temperature in Example 1 of Experiment 1 by means of a graph in comparison with Comparative Examples 1 and 3. In FIG. 4, Comparative Example 1 (PCW), Example 1 (GCW carbonization temperature; only the carbonization temperature is marked on the X-axis), and Comparative Example 3 (SCW) are each marked on the X-axis, and the intensity (no unit) is marked on the Y-axis.

FIG. 5 is a graph comparing the grain sizes of each crystal plane by using an XRD graph of a graphene/copper composite prepared according to the carbonization process temperature in Example 1 of Experiment 1 of the present disclosure and coppers in the Comparative Examples. In FIG. 5, Comparative Example 1 (PCW), Example 1 (GCW carbonization temperature), Comparative Example 2 (ACW), and Comparative Example 3 (SCW) are marked on the X-axis, and the crystal size (unit: nm) is marked on the Y-axis.

FIG. 6 is a graph showing a rate of increase in direct current (DC) and alternating current (AC) conductivities according to the frequency in the graphene/copper composite prepared according to the carbonization process temperature in Example 1 of Experiment 1 of the present disclosure in comparison with the conductivity of a pure copper wire. In FIG. 6, Example 1 (GCW carbonization temperature) is marked on the X-axis, and the Y-axis indicates a rate of increase in electrical conductivity (unit: %).

FIGS. 7A and 7B are XRD graphs of a graphene/copper composite prepared according to the carbonization process time in Example 2 of Experiment 1 of the present disclosure and coppers in the Comparative Examples. At this time, the concentration of the polymer solution is each 3.0% (FIG. 7A) and 5.0% (FIG. 7B) based on the weight of the solar solvent. In FIGS. 7A and 7B, an incident angle 2 theta (unit: degree) of X ray is marked on the X-axis, and the intensities (no unit) of pure polycrystalline copper (PCW) in Comparative Example 1, a graphene/copper composite for each time (GCW carbonization time) of the carbonization process in Example 2, heat-treated pure polycrystalline copper (ACW) in Comparative Example 2, and pure single crystalline copper (SCW) in Comparative Example 3 are marked on the Y-axis.

FIGS. 8A and 8B are graphs comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process time in Example 2 of Experiment 1 of the present disclosure and coppers in the Comparative Examples. At this time, the concentration of the polymer solution is each 3.0% (FIG. 8A) and 5.0% (FIG. 8B) based on the weight of the solar solvent. In FIGS. 8A and 8B, Comparative Example 1 (PCW), Example 2 (GCW carbonization time), Comparative Example 2 (ACW), and Comparative Example 3 (SCW) are marked on the X-axis, and the intensity ratios (no unit) are marked on the Y-axis.

FIGS. 9A and 9B are graphs comparing the grain sizes of each crystal plane by using an XRD graph of a graphene/copper composite prepared according to the carbonization process time in Example 2 of Experiment 1 of the present disclosure and coppers in the Comparative Examples. At this time, the concentration of the polymer solution is each 3.0% (FIG. 9A) and 5.0% (FIG. 9B) based on the weight of the solar solvent. In FIGS. 9A and 9B, Comparative Example 1 (PCW), Example 1 (GCW carbonization time), Comparative Example 2 (ACW), and Comparative Example 3 (SCW) are marked on the X-axis, and the crystal size (unit: nm) is marked on the Y-axis.

FIGS. 10A and 10B are graphs showing a rate of increase in direct current (DC) and alternating current (AC) conductivities according to the frequency in the graphene/copper composite prepared according to the carbonization process time in Example 2 of Experiment 1 of the present disclosure in comparison with the conductivity of a pure copper wire. At this time, the concentration of the polymer solution is each 3.0% (FIG. 10A) and 5.0% (FIG. 10B) based on the weight of the polar solvent. In FIGS. 10A and 10B, Example 2 (GCW carbonization time) is marked on the X-axis, and the Y-axis indicates a rate of increase in electrical conductivity (unit: %).

FIG. 11 is an XRD graph of a graphene/copper composite prepared according to the gas flow rate during the carbonization process in Example 3 of Experiment 1 of the present disclosure and coppers in the Comparative Examples. In FIG. 10, an incident angle (unit: degree) of X ray is marked on the X-axis, and the intensities (no unit) of a pure polycrystalline copper wire (PCW) in Comparative Example 1, a graphene/copper composite (hydrogen:argon flow rate (unit: sccm)) for each gas flow rate during the carbonization process (GCW carbonization time) of the carbonization process in Example 3, heat-treated pure polycrystalline copper (ACW) in Comparative Example 2, and pure single crystalline copper (SCW) in Comparative Example 3 are marked on the Y-axis.

FIG. 12 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the gas flow rate during the carbonization process in Example 3 of Experiment 1 of the present disclosure. In FIG. 12, Comparative Example 1 (PCW), Example 3 (hydrogen:argon flow rate (unit: sccm)), Comparative Example 2 (ACW), and Comparative Example 3 (SCW) are marked on the X-axis, and the intensity ratios (no unit) are marked on the Y-axis.

FIG. 13 is a graph comparing the grain sizes of each crystal plane by using an XRD graph of a graphene/copper composite prepared according to the gas flow rate during the carbonization process in Example 3 of Experiment 1 of the present disclosure. In FIG. 13, Comparative Example 1 (PCW), Example 3 (hydrogen:argon flow rate (unit: sccm)), Comparative Example 2 (ACW), and Comparative Example 3 (SCW) are marked on the X-axis, and the crystal sizes (unit: nm) are marked on the Y-axis.

FIG. 14 is a graph showing a rate of increase in direct current (DC) and alternating current (AC) conductivities according to the frequency in the graphene/copper composite prepared according to the gas flow rate during the carbonization process in Example 3 of Experiment 1 of the present disclosure in comparison with the conductivity of a pure copper wire. In FIG. 14, Example 3 (hydrogen:argon flow rate (unit: sccm)) is marked on the X-axis, and the Y-axis indicates a rate of increase in electrical conductivity (unit: %).

FIG. 15 is an XRD graph of a graphene/copper composite prepared according to the carbonization process pressure in Example 4 of Experiment 1 of the present disclosure. In FIG. 15, an incident angle (unit: degree) of X ray is marked on the X-axis, and the intensities (no unit) of pure polycrystalline copper (PCW) in Comparative Example 1, a graphene/copper composite for each pressure (GCW pressure) of the carbonization process in Example 4, heat-treated pure polycrystalline copper (ACW) in Comparative Example 2, and pure single crystalline copper (SCW) in Comparative Example 3 are marked on the Y-axis.

FIG. 16 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process pressure in Example 4 of Experiment 1 of the present disclosure. In FIG. 16, Comparative Example 1 (PCW), Example 4 (GCW pressure), Comparative Example 2 (ACW), and Comparative Example 3 (SCW) are marked on the X-axis, and the intensity ratios (no unit) are marked on the Y-axis.

FIG. 17 is a graph comparing the grain sizes of each crystal plane by using an XRD graph of a graphene/copper composite prepared according to the carbonization process pressure in Example 4 of Experiment 1 of the present disclosure. In FIG. 17, Comparative Example 1 (PCW), Example 4 (GCW pressure), Comparative Example 2 (ACW), and Comparative Example 3 (SCW) are marked on the X-axis, and the crystal size (unit: nm) is marked on the Y-axis.

FIG. 18 is a graph showing a rate of increase in direct current (DC) and alternating current (AC) conductivities according to the frequency in the graphene/copper composite prepared according to the carbonization process pressure in Example 4 of Experiment 1 of the present disclosure in comparison with the conductivity of a pure copper wire. In FIG. 18, Example 4 (GCW pressure) is marked on the X-axis, and the Y-axis indicates a rate of increase in electrical conductivity (unit: %).

FIG. 19 is an XRD graph of a graphene/copper composite prepared in the presence and absence of a change in temperature during the carbonization process in Example 5 of Experiment 1 of the present disclosure and the Comparative Examples. In FIG. 19, an incident angle 2 theta (unit: degree) of X ray is marked on the X-axis, and the intensities (no unit) of pure polycrystalline copper (PCW) in Comparative Example 1, a graphene/copper composite in the presence and absence of a change in temperature (change in GCW temperature) during the carbonization process in Example 5, heat-treated pure polycrystalline copper (ACW) in Comparative Example 2, and pure single crystalline copper (SCW) in Comparative Example 3 are marked on the Y-axis.

FIG. 20 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared in the presence and absence of a change in temperature during the carbonization process in Example 5 of Experiment 1 of the present disclosure and coppers in the Comparative Examples. In FIG. 20, Comparative Example 1 (PCW), Example 5 (change in GCW temperature), Comparative Example 2 (ACW), and Comparative Example 3 (SCW) are marked on the X-axis, and the intensity ratios (no unit) are marked on the Y-axis.

FIG. 21 is a graph comparing the grain sizes of each crystal plane by using an XRD graph of a graphene/copper composite prepared in the presence or absence of a change in temperature during the carbonization process temperature in Example 5 of Experiment 1 of the present disclosure and coppers in the Comparative Examples. In FIG. 21, Comparative Example 1 (PCW), Example 5 (change in GCW temperature), Comparative Example 2 (ACW), and Comparative Example 3 (SCW) are marked on the X-axis, and the crystal size (unit: nm) is marked on the Y-axis.

FIG. 22 is a graph showing a rate of increase in direct current (DC) and alternating current (AC) conductivities according to the frequency in the graphene/copper composite prepared according to the change in temperature during the carbonization process in Example 5 of Experiment 1 of the present disclosure in comparison with the conductivity of a pure copper wire. In FIG. 22, Example 5 (change in GCW temperature) is marked on the X-axis, and the Y-axis indicates a rate of increase in electrical conductivity (unit: %).

FIG. 23 shows the ratios of contents of copper and copper oxide of a graphene/copper composite prepared according to the carbonization process temperature in Example 1 and the Comparative Examples.

FIG. 24 is an XRD graph of a graphene/copper composite film structure prepared according to the carbonization process temperature in Example 6 of Experiment 1 of the present disclosure and a pure copper film in Comparative Example 4. In FIG. 24, an incident angle (unit: degree) of X ray is marked on the X-axis, and XRD intensities (no unit) of a pure copper film (PCF) in Comparative Example 4 and a graphene/copper composite film structure (GCF carbonization temperature) for each temperature of the carbonization process in Example 6 are marked on the Y-axis.

FIG. 25 is an XRD graph of a graphene/copper composite film structure prepared according to the carbonization process time in Example 7 of Experiment 1 of the present disclosure and a pure copper film in Comparative Example 4. In FIG. 25, an incident angle (unit: degree) of X ray is marked on the X-axis, and XRD intensities (no unit) of a pure copper film (PCF) in Comparative Example 4 and a graphene/copper composite film structure (GCF carbonization time) for each time of the carbonization process in Example 7 are marked on the Y-axis.

FIG. 26 is an XRD graph of a graphene/aluminum composite wire structure prepared according to the gas atmosphere in Example 1 of Experiment 2 of the present disclosure and the Comparative Examples.

FIG. 27 is an XRD graph of a graphene/aluminum composite prepared according to the polymer concentration in Example 2 of Experiment 2 of the present disclosure and the Comparative Examples.

FIG. 28 is an exemplary schematic view for describing the concepts of single crystal and polycrystal.

### DETAILED DESCRIPTION

Hereinafter, exemplary embodiments of the present disclosure will be described in detail.

In the present specification, a carbon material means a material including a hexagonal carbon structure, and the carbon material may include a polygonal carbon structure except for, for example, a hexagon where a portion of the crystallinity deteriorates, and a cyclic carbon structure where defects are partially present or a non-crystalline carbon, but consists mainly of graphene, and may also consist only of graphene.

In the present specification, a polycrystalline metal means a metal which is partially a crystal, but is not one uniform crystal on the whole.

In the present specification, a single crystalline metal means a metal in which a regular arrangement of metal atoms is uniformly formed in the entire metal.

In the present specification, the ratio of a crystal plane of a polycrystal means a ratio of the XRD intensity of the other crystal plane to the XRD intensity of a specific crystal plane of the polycrystal.

In the present specification, a change in ratio of a crystal plane of a polycrystalline metal means that when a carbonization material is formed on a surface of the polycrystalline metal by performing a heat treatment after providing a polymer on the surface of the polycrystalline metal, and the ratio of the crystal plane of the polycrystalline metal in which the carbonization material is formed is changed in a manner different from a ratio of the crystal plane of a polycrystalline metal on which no treatment is performed itself or the polycrystalline metal prior to the heat treatment.

In the present specification, a single crystal-like metal means that growth of a specific crystal plane of a polycrystal is induced or suppressed, and as a result, the ratio of the crystal plane of the polycrystal is changed, and the metal is not a single crystal, but the ratio of a specific crystal plane predominantly appears in a manner similar to the single crystal.

In the present specification, the predominance of the ratio of the specific crystal plane means the case where based on the XRD intensity of the crystal plane, which exhibits the highest XRD intensity, the XRD intensities of the other crystal planes are 90% or less.

In the present specification, zero dimension means that there is no difference in thickness, length, and breadth by 1 order (10 times) or more (for example, small particle type), and one dimension means that there is a difference between breadth and length by 1 order or more, there is a difference between elongated breadth (or length) and thickness by 1 order or more, and there is no difference between short length (or breadth) and thickness by 1 order or more (for example, linear). Further, in the present specification, two dimension means that there is no difference between breadth and length by 1 order or more, there is a difference between thickness and breadth by 1 order or more, and there is also a difference between thickness and length by 1 order or more (for example, a film type or a flat plate type). In the present specification, three dimension means that the 2-dimensional films are stacked.

In the present specification, a maximum allowable current density means a maximum allowable current value which can flow per unit area. For example, in the case of an electric wire, damage or fire of an wire insulating material due to excessive electric current should not occur, so that a maximum allowable current density (allowable current/electric wire cross-sectional area) which can safely flow through the electric wire is defined.

When a carbon material, for example, graphene is formed (grown) by performing a heat treatment after forming a polymer on the surface of a metal, and growth of a specific crystal plane of a polycrystal is promoted or suppressed by forming (growing) the carbon material, and growth of the other crystal planes is suppressed or promoted. According to the foregoing matter, the ratio between crystal planes is changed as compared to the case where the polycrystalline metal is only subjected to heat treatment without forming a carbon material. When the polycrystalline metal is only subjected to heat treatment, only the grain size is increased, and the ratio between crystal planes is little changed.

As a result, the ratio of the crystal plane may be selectively adjusted, and ultimately, the ratio of the crystal plane of the polycrystal may be adjusted so as to be similar to that of the single crystal. As described above, when the crystal plane is controlled so as to be similar to that of the single crystal, the resistance caused by the difference between crystal planes is reduced, or preferably may disappear. Further, there is an advantage in that characteristics similar to those of the single crystal may be implemented by using a polycrystalline metal which has low preparation costs and can be mass-produced

When the associated mechanism is described in more detail, if the metal is heat-treated for crystal growth of the metal, a specific crystal plane of the metal is grown.

For example, in the case of polycrystalline copper, when XRD graphs of pure copper and copper subjected to heat treatment are compared with each other, the copper crystal growth rate toward the (111) plane in the crystal planes of copper is predominant. By the way, when a polymer coating layer is formed on a metal, and carbonization is performed at a temperature of, for example, 700° C. or less, a carbon material, for example, graphene is formed while the polymer of the polymer coating layer is carbonized.

When the carbon material is formed, the carbon material growth rate on the other crystal planes other than the (111) plane of copper, for example, the (200) plane is faster than the crystal growth rate toward the (111) plane of copper, so that in a finally formed metal-carbon material composite, the (111) plane predominantly developed when a heat treatment is performed without forming the carbon material is rather suppressed, and the other crystal planes, for example, the (200) plane may become a developed structure.

When a carbon material is formed by forming a polymer layer on a metal, and then performing a heat treatment as described above, it is contemplated that the occurrence of a change in growth of the crystal plane is attributed to the interaction between the crystal planes of a polycrystalline metal and a polymer, and between a gas formed from the polymer and the carbon material.

When the reason is more specifically examined, it is contemplated that the first coated polymer itself changes the surface energy of the metal. The polymer coated on the surface of the metal may lower the surface energy of the specific crystal plane of the metal at a predetermined temperature, thereby inducing the growth of the crystal plane.

Further, the coated polymer may be decomposed to form a specific gas, thereby lowering the surface energy of the metal. Since a polymer has a long molecular length, various gases may be generated. The surface energy of the specific crystal plane of the metal is lowered by a gas generated in the largest amount, and the crystal plane may be grown by the lowered surface energy. The mechanism will be described below, but even though one surface plane of a metal coated with a polymer is grown, it is observed that the other crystal planes are relatively maintained, and it is contemplated that the maintenance of the other crystal planes is also associated with formation of various gases.

That is, when the polymer is decomposed during the carbonization procedure as described above, various gases are generated, and the crystal plane of the metal, which lowers the surface energy, varies depending on the type of each gas. If only one gas is generated, the metal is only grown toward the specific crystal plane by the gas. However, since various gases are generated in the actual carbonization process, it can be seen that the growth of a specific crystal plane of the metal by a gas generated in the largest amount is predominant, and simultaneously, the other crystal planes are also relatively maintained due to the influences caused by the other gases.

Further, there may occur a growth or suppression of a crystal plane of a metal caused by the growth of the carbon material. For example, when copper and graphene are taken as an example, in the case of copper, graphene is most rapidly grown on the (111) plane. Even on the other crystal planes, graphene is grown, but the reaction rate on the (111) plane is fast, and a high-quality (the number of layers of graphene is easily adjusted, and the content of amorphous carbon is small) graphene may be formed. When graphene is formed on the (111) plane of copper as described above, graphene serves as a capping layer when the crystal plane is grown at high temperature to remove a site to which copper atoms are attached, so that it is contemplated that the (111) crystal plane is suppressed from being grown, and growth of the other crystal planes is promoted. In this regard, the formation of graphene lowers electrical conductivity of the metal wire.

As described above, when a metal is coated with a polymer and a heat treatment is performed, a change in surface energy of the metal crystal plane occurs due to the polymer or the gas generated from the polymer, and accordingly, the specific crystal plane is grown (or suppressed), and the other crystal planes may be suppressed (or grown) or vice versa. Further, by the capping effects of a carbon material formed from a polymer, the growth of the specific crystal plane may be suppressed (or promoted), and the growth of the other crystal planes may be promoted (or suppressed).

Thus, in another exemplary embodiment, the present disclosure provides a method for controlling a crystal plane of a polycrystalline metal, in which a carbonization material is formed on a surface of the polycrystalline metal by performing a heat treatment after providing a polymer on the surface of the polycrystalline metal, and growth of a specific crystal plane of the polycrystalline metal is promoted or suppressed, so that a ratio of the crystal plane of the polycrystalline metal is changed differently from a ratio of the crystal plane of the polycrystalline metal prior to the heat treatment.

In an exemplary embodiment, the method includes: a first step of providing the polymer on the a surface of a polycrystalline metal; and a second step of carbonizing the polymer provided on the surface of the polycrystalline metal to the carbon material by subjecting the polycrystalline metal and the provided polymer to the heat treatment.

In an exemplary embodiment, the ratio of the crystal plane may be controlled by adjusting one or more of the coating conditions under which the surface of the polycrystalline metal is coated with a polymer and the carbonization conditions through the heat treatment.

The growth rate of carbon material for the specific crystal plane and the resulting crystal plane may be controlled by adjusting the coating conditions and the carbonization conditions. For example, the growth rate may be controlled according to the polymer coating conditions such as type, concentration, and molecular weight of a polymer, coating rate, solvent drying rate, and thickness of a polymer film, or the carbonization conditions such as carbonization temperature, presence or absence of a change in carbonization temperature, carbonization time, carbonization process atmosphere (process gas), and carbonization pressure. Since the formation rate and ratio of the carbon material finally formed on the surface of the metal may depend on the above-described coating conditions, all of the coating and carbonization conditions affect the control of the crystal plane.

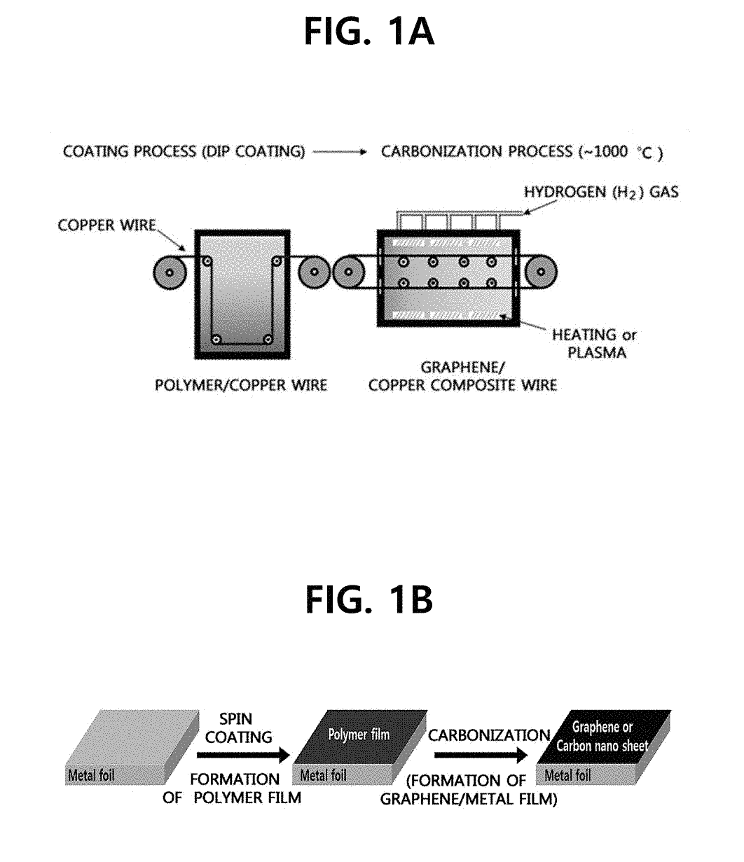

FIGS. 1A and 1B are schematic views showing a continuous procedure of controlling a crystal plane of a metal according to an exemplary embodiment of the present disclosure. FIG. 1A schematically shows an example of forming a composite wire of graphene and copper by forming graphene as a carbon material in a metal wire. FIG. 1B schematically shows an example of forming a composite of graphene and a metal film by forming a polymer film on a metal foil and carbonizing the polymer film.

Referring to FIGS. 1A and 1B, in the first step, the surface of the metal is coated with a polymer by providing the metal with a polymer solution and removing the solvent, and then the polymer provided on the metal wire is carbonized with a carbon material by subjecting the metal wire and the provided polymer to heat treatment.

Hereinafter, the preparation method will be each described in detail.

First, in the first step, a polymer thin film having a thickness of several to several hundred nanometers on the surface of a metal. In order to form a polymer thin film, the polymer thin film can be prepared by using, for example, spin coating, dip coating, bar coating, self assembly, a spray method, and inkjet printing, gravure, and gravure-offset capable of preparing a polymer thin film in a selective region, flexography, a screen-printing method, and a nano imprinting method either alone or one or more thereof.

Further, as a precursor polymer which forms a carbon material, it is possible to use a homopolymer or co-polymer of monomers of a polymer including polyacrylonitrile (PAN), polymers of intrinsic microporosity (PIMs), pitch, lignin, cellulose, polyimide (PI), rayon, and the like, or a mixture in which one or more of these polymers are used. In the non-limiting example to be described below, a PAN polymer was used.

In the non-limiting example, polyacrylonitrile may have a weight average molecular weight of 800,000 or less, preferably 118,000 to 520,000.

In the non-limiting example, polymers of intrinsic microporosity may have a weight average molecular weight of 50,000 or less.

In the non-limiting example, pitch may have a weight average molecular weight of 10,000 or less, preferably 100 to 1,500.

In the non-limiting example, rayon may have a weight average molecular weight of 10,000 or less.

In the non-limiting example, polyimide may have a weight average molecular weight of 800,000 or less, preferably 100,000 to 500,000.

In the non-limiting example, lignin may have a weight average molecular weight of 10,000 or less.

In the non-limiting example, cellulose may have a weight average molecular weight of 300,000 or less.

A polymer solution may be prepared by putting these precursor polymers into a solvent, and at this time, the aspect of controlling the crystal plane of the polycrystalline metal may vary by adjusting the concentration. Here, the concentration of the polymer refers to the content of polymer dissolved in a polymer solution, and for example, a 5 wt % polymer concentration means that in 100 g of the polymer solution, the weight of the polymer is 5 g and the weight of the solvent is 95 g.

Specifically, when the carbonization conditions are the same as each other, but only the concentration of the polymer solution is changed, the growth rate of the carbon material on the surface of the metal is increased as the concentration of the solution is generally increased (that is, the amount of the carbon source is increased), and the metal crystal plane where the growth of the carbon material is predominant is suppressed from being grown due to the capping role of the carbon material. However, since the growth rate of the carbon material does not always have a proportional relationship with the concentration of the polymer, and rather hinders the growth of crystal grains toward a single crystal-like metal after the concentration of the polymer reaches a predetermined concentration (the case where the amount of a carbon source is much higher than necessary), an appropriate polymer concentration is required.

As described above, the amount (thickness of the polymer) of the carbon source affects the growth rate of the carbon material formed on the surface of the metal, and a specific crystal plane may be suppressed (or grown) by capping effects of the carbon material.

Meanwhile, the thickness of the polymer is adjusted by the molecular weight of the polymer, coating rate, the frequency of coatings, and the like in addition to the aforementioned concentration of the polymer. In general, the higher the molecular weight of the polymer, the lower the coating rate, and the higher the frequency of coatings, the higher the thickness of the polymer coated on the surface of the metal becomes. However, since the growth rate of the carbon material is not linear with each factor similarly to the concentration of the polymer, an appropriate thickness of the polymer, which does not hinder the growth of crystal grains toward the single crystal-like metal, needs to be formed, and coating conditions such as a molecular weight of the polymer, coating rate, number of coatings, and the like need to be adjusted so as to be suitable for the requirements.

Furthermore, the growth of a specific crystal plane of a metal can be induced by lowering the surface energy of the specific crystal plane, and the surface energy is affected by the polymer itself coated on the surface of the metal and a specific gas formed when the polymer is decomposed (carbonization process). Accordingly, since the type (structure) of polymer is different from gas released by the decomposition reaction of the polymer in terms of type and amount, the specific crystal plane of the metal of which the surface energy is lowered may depend on the type (structure) of polymer.

In the non-limiting example, the concentration of polymer in the polymer solution may be 1 wt % to 15 wt %.

In the non-limiting example, the prepared polymer thin film may have a thickness of 1 nm to 1,000 nm, more preferably, 1 nm to 100 nm. The thickness may be adjusted through the content (concentration) of the polymer in the solution and the type of polymer, and the like, as described above.

In the non-limiting example, a metal, which supports the polymer thin film, can be prepared by using, for example, one or more polycrystalline metals selected from a group consisting of transition metals including one or more of Pt, Ru, Cu, Fe, Ni, Co, Pd, W, Ir, Rh, Sr, Ce, Pr, Nd, Sm, or Re, alloys of the transition metals, non-transition metals including one or more of Mg, B, or Al, and alloys of the transition metals.

In the non-limiting example, the metal may have a multi-dimensional structure (zero dimension, one dimension, two dimension, or three dimension).

For example, the metal can be used in various forms, such as a metal film (or foil, plate), and a metal wire form.

Next, the second step induces a carbon material/metal composite by subjecting the polymer/metal to heat treatment.

In the non-limiting example, the polymer/metal may be carbonized under the conditions of 400° C. to 1,800° C. under an atmosphere of an inert gas including one or more gases of an inert gas, hydrogen, and the like, or a vacuum atmosphere.

In the non-limiting example, preferably when the metal is copper, copper may be carbonized under the conditions of 500° C. to 1,000° C. under a hydrogen atmosphere, and under the conditions of pressure less than atmospheric pressure for 60 minutes or less.

Meanwhile, the carbon material prepared in the second step has a thickness of 1 layer to 300 layers. A carbon material/metal composite prepared in this step has a diameter of 10 nm to 100 cm, and the length can be continuously prepared.

In the non-limiting example, a stabilization process may be added in order to control the thickness and uniform formation of the carbon material in the second step. When the stabilization process is performed, the thickness of the polymer thin film may vary. As described above, a change in crystal plane may be controlled by adjusting the thickness of the polymer thin film, and the stabilization process affects the adjustment of the thickness of the polymer thin film. Meanwhile, characteristics of a final carbon material may depend on the degree of oxidation of the surface of the metal, which is exposed during the stabilization process.

The stabilization reaction may induce a chemical stabilization reaction by subjecting the polymer to a heat treatment at a temperature of 400° C. or less under an air, oxygen, or vacuum atmosphere, or using an aqueous strong alkaline solution or a strong alkaline organic solution, or may induce a stabilization reaction by using plasma, ion beam, radiation, UV irradiation, microwave, and the like. Further, a stabilization reaction may be induced by using a co-monomer to change the structure of polymer chains or chemically cross-linking polymer chains.

A method for forming a polymer on the surface of a metal and carbonizing the polymer as described above becomes a peculiar method which controls a crystal plane of a polycrystalline metal. That is, in the case of other methods for growing a carbonization material, such as, for example, a CVD method, a carbon material such as graphene is deposited in a state where the temperature is already increased, so that the crystal plane of the metal is already changed prior to the deposition of the carbon material, and as a result, the ratio of the crystal plane is not changed regardless of whether the carbon material is formed, and only the grain size is increased.

On the other hand, according to the method for forming a polymer on the surface of a metal, and then carbonizing the polymer as described above, the ratio of the crystal plane of the metal may be variously changed by coating the surface of the polycrystalline metal with a polymer and forming a carbon material through a heat treatment.

Meanwhile, in exemplary embodiments of the present disclosure, a metal-carbon material composite obtained by the above-described method for preparing the crystal plane of the metal is a metal-carbon material composite where the carbon material is formed on the surface of the polycrystalline metal, in which the carbon material is formed through a heat treatment of a polymer on the surface of the metal, and a growth of a specific crystal plane of the polycrystalline metal is promoted or suppressed by forming the carbon material. Further, by formation of the carbon material, the ratio of the crystal plane may be changed in comparison with the case where the polycrystalline metal is subjected to heat treatment without forming the carbon material.

In an exemplary embodiment, the change in ratio of a crystal plane changes the ratio between crystal planes in the XRD graph (that is, the ratio of intensities of the other crystal planes to a specific crystal plane in the XRD graph) of a polycrystalline metal subjected to no treatment itself or in the case where the polycrystalline metal is subjected to heat treatment without forming the carbon material (in this case, the ratio of crystal planes is not changed) by at least 5%, preferably 10% or more.

In an exemplary embodiment, the metal of the metal-carbon material composite may be a quasi-single crystal controlled so as for the ratio of the specific crystal plane to become predominant.

In an exemplary embodiment, when in the XRD graph of the polycrystalline metal after heat treatment, the intensity of a crystal plane having the highest intensity, that is, a predominant crystal plane is assumed to be 1, the intensities of the other crystal planes may be 0 or more than 0 and 0.9 or less. For reference, the case where the intensities of the other crystal planes are 0 corresponds to a single crystal.

Alternatively, in an exemplary embodiment, when in the XRD graph of the polycrystalline metal after heat treatment, the intensity of a crystal plane having the highest intensity, that is, a predominant crystal plane is assumed to be 1, the intensities of the other crystal planes may be 0 or more than 0 and 0.5 or less.

Alternatively, in an exemplary embodiment, when in the XRD graph of the polycrystalline metal after heat treatment, the intensity of a crystal plane having the highest intensity, that is, a predominant crystal plane is assumed to be 1, the intensities of the other crystal planes may be 0 or more than 0 and 0.1 or less.

For example, if the intensity of the (200) plane is predominant, when I₍₂₀₀₎ is assumed to be 1, I₍₁₁₁₎ and I₍₂₂₀₎ being the intensities of the other crystal planes may be each 0 or in a range of 0<I₍₁₁₁₎ and I₍₂₂₀₎≤0.9 (or 0.5 or 0.1).

In the non-limiting example, when I₍₂₀₀₎=1, I₍₁₁₁₎ and I₍₂₂₀₎ may represent 0.53 and 0.3, respectively.

In an exemplary embodiment, the metal-carbon material composite may have a conductivity of 10³ S/cm to 10⁸ S/cm.

Further, in another exemplary embodiment, the metal-carbon material composite may have an elasticity of 0.1 GPa to 1,000 GPa.

In addition, in another exemplary embodiment, a maximum allowable current density of the metal-carbon material composite may be more than 100% and 10,000% or less based on that of the polycrystalline metal before the carbon material is formed.

In another exemplary embodiment, the metal-carbon material composite may be applied to an electric wire, or various electronic or energy devices such as an energy device and an electromagnetic wave shielding material.

Hereinafter, a specific example according to exemplary embodiments of the present disclosure will be described in more detail. However, the present disclosure is not limited to the following Example, and various forms of examples can be implemented within the accompanying claims, and it is to be understood that the following Example only completes the disclosure of the present disclosure and allows a person with ordinary skill in the art to easily carry out the present disclosure.

For the graphene/metal composites in the following Examples, as the process flow shown in FIGS. 1A and 1B, a metal was immersed in a polyacrylonitrile (PAN) solution dissolved in dimethylformamide (DMF) being a polar organic solvent at a predetermined rate to coat the surface of the metal with a polymer thin film. The polymer/metal composite, on which the polymer thin film was formed, was carbonized in a carbonization furnace where the gas atmosphere was controlled.

[Experiment 1: Copper Wire]

### EXAMPLE 1

In order to confirm a change in crystal plane of a copper wire according to the synthesis temperature and a correlation with the electrical conductivity of a graphene/copper composite wire for the change, a polycrystalline copper wire with a diameter of 0.192 mm and a length of 1.8 m was provided, and a polymer solution having a low concentration of 3.0% based on the weight of a polar solvent was prepared.

The polar solvent was N,N-dimethylformamide (DMF), and the polymer is polyacrylonitrile (PAN). The used polyacrylonitrile (PAN) had a molecular weight 150,000 g/mol, and a carbonization yield of 40% to 50%.

As a coating method, dip coating was used to coat the entire surface. The coating rate was set to be 0.5 m/min, and the drying time was set to be 1 hour. The coating thickness was about 50 nm.

That is, a copper wire was immersed in a polymer solution at the rate for several seconds, taken out from the solution, and then dried under air atmosphere. The temperature during the coating and drying was room temperature (25° C.) and the relative humidity was 40% or less.

Subsequently, a carbonization treatment was performed for 90 minutes while increasing the temperature to a temperature of 500° C., 600° C., 700° C., 800° C., 900° C., and 1,000° C. under a hydrogen gas atmosphere at a flow rate of 5 sccm. For the pressure during the carbonization, the carbonization treatment was performed under a low pressure of about 70 mTorr.

Accordingly, a change in crystal plane of the copper wire occurred, and simultaneously, the polymer was formed as a graphene/copper composite structure while being carbonized.

### COMPARATIVE EXAMPLE 1

The copper wire with a diameter of 0.192 mm used in Example 1 was provided with a pure copper wire (PCW) including no polymer.

### COMPARATIVE EXAMPLE 2

The copper wire with a diameter of 0.192 mm used in Example 1 was provided with a copper wire (ACW) in which a polymer was not included and only a heat treatment was performed.

### COMPARATIVE EXAMPLE 3

A pure single crystalline copper wire (SCW) having a diameter of 0.102 mm was provided instead of the polycrystalline copper wire used in Example 1.

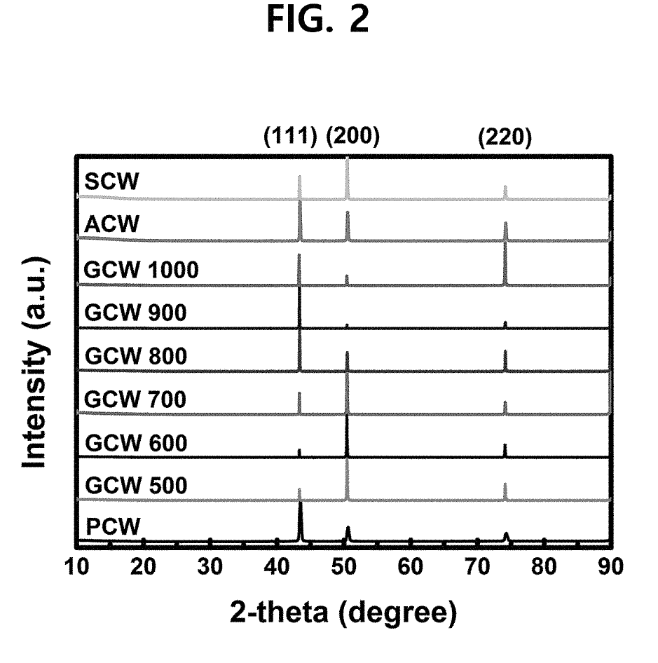

FIG. 2 is an XRD graph of a graphene/copper composite prepared according to the carbonization process temperature in Example 1 of Experiment 1 of the present disclosure and coppers in the Comparative Examples. In FIG. 2, an incident angle 2 theta (unit: degree) of X ray is marked on the X-axis, and the intensities (no unit) of pure polycrystalline copper (PCW) being Comparative Example 1, a graphene/copper composite for each temperature (GCW carbonization temperature) of the carbonization process in Example 1, heat-treated pure polycrystalline copper (ACW) in Comparative Example 2, and pure single crystalline copper (SCW) in Comparative Example 3 are marked on the Y-axis.

It can be confirmed that (111), (200), and (220) of copper were commonly observed.

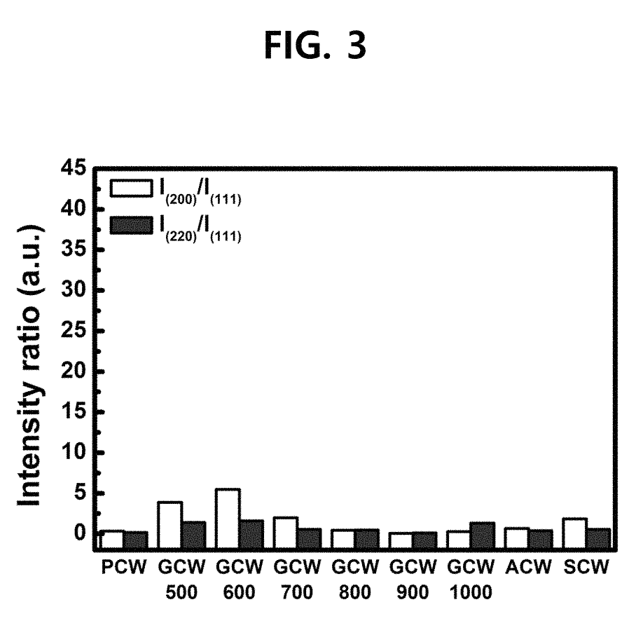

FIG. 3 is a graph comparing the intensity ratios of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process temperature in Example 1 of Experiment 1 of the present disclosure and coppers in the Comparative Examples. In FIG. 3, Comparative Example 1 (PCW), Example 1 (GCW carbonization temperature), Comparative Example 2 (ACW), and Comparative Example 3 (SCW) are each marked on the X-axis, and the intensity ratios (no unit) are marked on the Y-axis.

As shown in FIGS. 2 and 3, when the carbonization temperature was less than 800° C., the growth of (111) was suppressed and (200) was developed unlike the pure copper wire (PCW). In contrast, when the carbonization temperature was 800° C. or more, a tendency similar to that of the pure copper wire (PCW) was shown.

The following table shows a change in intensity of each crystal plane of copper according to each carbonization process temperature by means of a table. In the following Table 1, the intensity of a plane exhibiting the highest intensity in (111), (200), and (220) of copper, that is, a predominant plane was assumed to be 1.

TABLE 1

| | I (111) | I (200) | I (220) |
|---|---|---|---|
| PCW | 1 | 0.38 | 0.23 |
| GCW 500 | 0.26 | 1 | 0.38 |
| GCW 600 | 0.18 | 1 | 0.30 |
| GCW 700 | 0.50 | 1 | 0.29 |
| GCW 800 | 1 | 0.44 | 0.47 |
| GCW 900 | 1 | 0.08 | 0.13 |
| GCW 1000 | 0.71 | 0.22 | 1 |
| SCW | 0.53 | 1 | 0.30 |

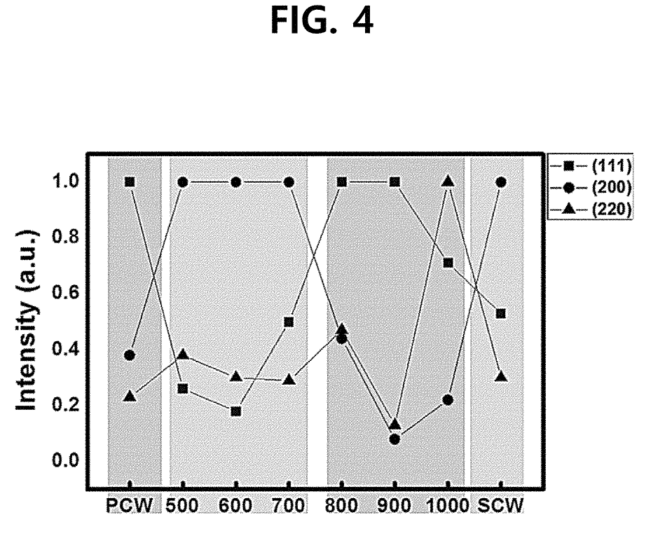

Further, FIG. 4 is an indication of a change in intensity of each crystal plane of copper according to the carbonization process temperature in Example 1 of the present disclosure as a graph in comparison with Comparative Examples 1 and 3. In FIG. 4, Comparative Example 1 (PCW), Example 1 (GCW carbonization temperature), and Comparative Example 3 (SCW) are each marked on the X-axis, and the intensity (no unit) is marked on the Y-axis.

As can be seen from Table 1 and FIG. 4, when the synthesis temperature is 500° C. to 700° C., particularly 700° C., the change in crystal plane of copper becomes similar to that of the single crystalline copper wire (SCW).

Further, when the intensity of the crystal plane of the graphene/copper composite wire synthesized in the temperature range is expressed as a ratio obtained by assuming a crystal plane having the highest intensity in each of the three crystal planes, that is, a predominant crystal plane to be 1 and diving the others, I₍₂₀₀₎=1, 0<I₍₁₁₁₎ and I₍₂₂₀₎≤0.9.

Likewise, when the synthesis temperature is 800° C. to 1,000° C., the XRD tendency becomes similar to the XRD tendency of the pure copper wire (PCW), and it can be seen that when the intensity is expressed as a ratio obtained by assuming a crystal plane having the highest intensity in each of the three crystal planes, that is, a predominant crystal plane to be 1 and diving the others, the change in crystal plane occurs so as to be I₍₁₁₁₎=1, 0<I₍₂₀₀₎ and I₍₂₂₀₎≤0.9.

For reference, the intensity of the crystal plane may vary depending on the metal used, the polymer, the carbonization conditions, and the like. For example, the (200) plane may be the highest, and in other cases, the (111) plane may be higher. In terms of electrical conductivity, and the like, it is important to allow the growth of the specific crystal plane to be predominant, that is, to be a quasi-single crystal, but the predominant crystal plane need not always be a specific crystal plane such as the (200) plane or the (100) plane.

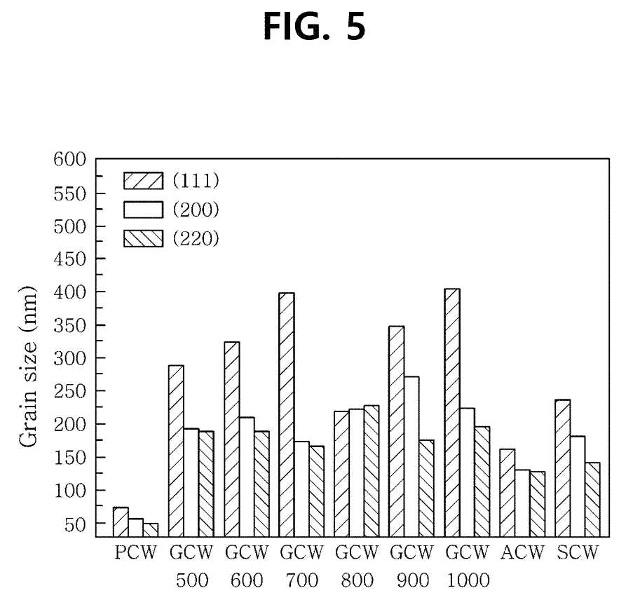

FIG. 5 is a graph comparing the grain sizes of each crystal plane by using an XRD graph of a graphene/copper composite prepared according to the carbonization process temperature in Example 1 of Experiment 1 of the present disclosure and coppers in the Comparative Examples. In FIG. 5, Comparative Example 1 (PCW), Example 1 (GCW carbonization temperature), Comparative Example 2 (ACW), and Comparative Example 3 (SCW) are marked on the X-axis, and the crystal size (unit: nm) is marked on the Y-axis.

As seen in FIG. 5, there is no significant effect on the change in size of the crystal plane of copper according to the carbonization process temperature.

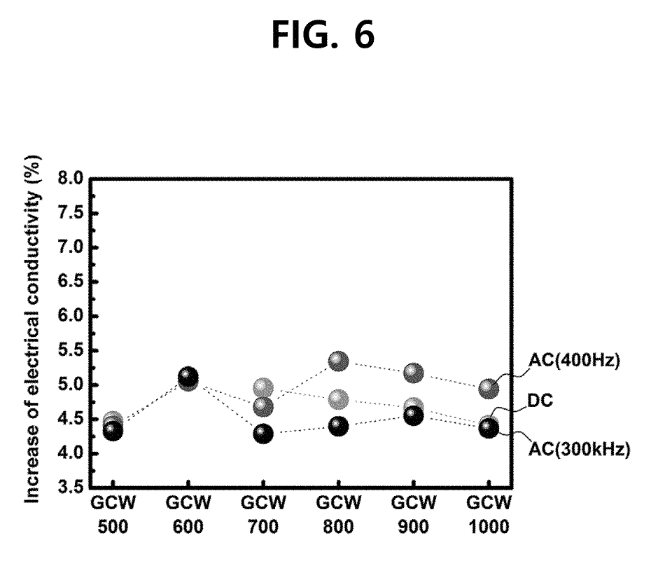

FIG. 6 is a graph showing a rate of increase in direct current (DC) and alternating current (AC) conductivities according to the frequency in the graphene/copper composite prepared according to the carbonization process temperature in Example 1 of Experiment 1 of the present disclosure in comparison with the conductivity of a pure copper wire. In FIG. 6, Example 1 (GCW carbonization temperature) is marked on the X-axis, and the Y-axis indicates a rate of increase in electrical conductivity (unit: %).

When the ratios of XRD intensities in FIGS. 2 and 3 are compared with a rate of increase in electrical conductivity, it can be confirmed that the carbonization process temperature does not significantly affect the ratios of XRD intensities and the rate of increase in electrical conductivity.

### EXAMPLE 2

A graphene/copper composite wire was prepared through the same process, except for the concentration of the polymer solution, the carbonization process temperature, and time in Example 1. The copper wire was coated by using a polymer solution in an amount of each 3.0% and 5.0% based on the weight of the polar solvent. Subsequently, a carbonization treatment was performed for each of 30, 60, and 90 minutes by increasing the temperature to 700° C.

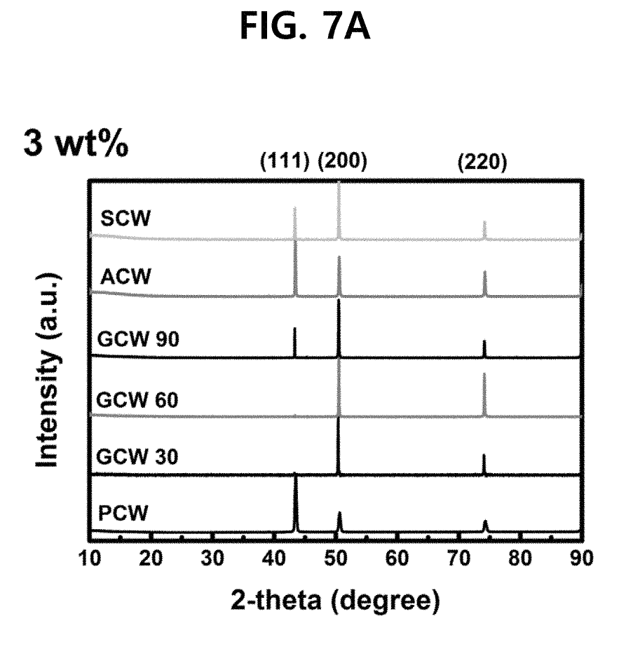

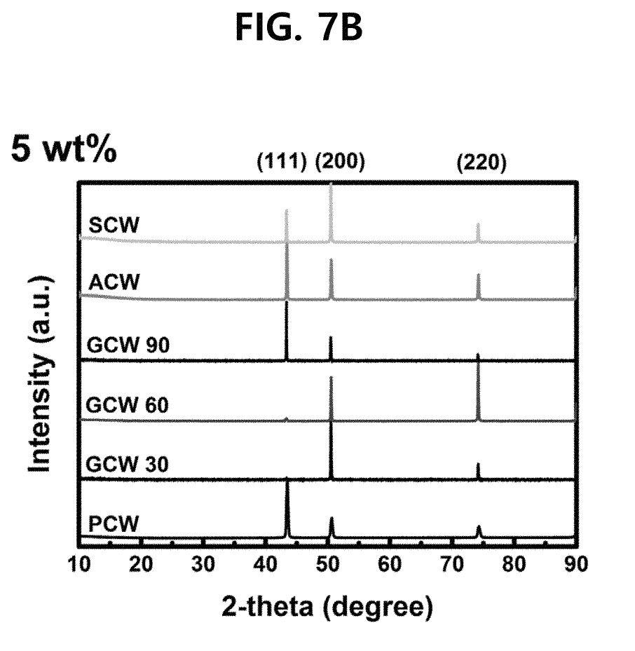

FIGS. 7A and 7B are XRD graphs of a graphene/copper composite prepared according to the carbonization process time in Example 2 of Experiment 1 of the present disclosure and coppers in the Comparative Examples. At this time, the concentration of the polymer solution is each 3.0% (FIG. 7A) and 5.0% (FIG. 7B) based on the weight of a polar solvent. In FIGS. 7A and 7B, an incident angle 2 theta (unit: degree) of X ray is marked on the X-axis, and the intensities (no unit) of pure polycrystalline copper (PCW) in Comparative Example 1, a graphene/copper composite for each temperature (GCW carbonization temperature) of the carbonization process in Example 1, heat-treated pure polycrystalline copper (ACW) in Comparative Example 2, and pure single crystalline copper (SCW) in Comparative Example 3 are marked on the Y-axis.

As shown in FIGS. 7A and 7B, it can be confirmed that (111), (200), and (220) of copper were commonly observed.

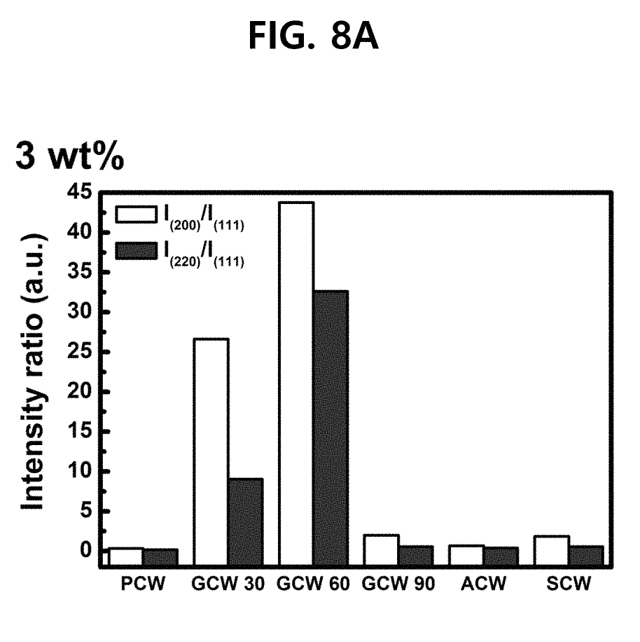

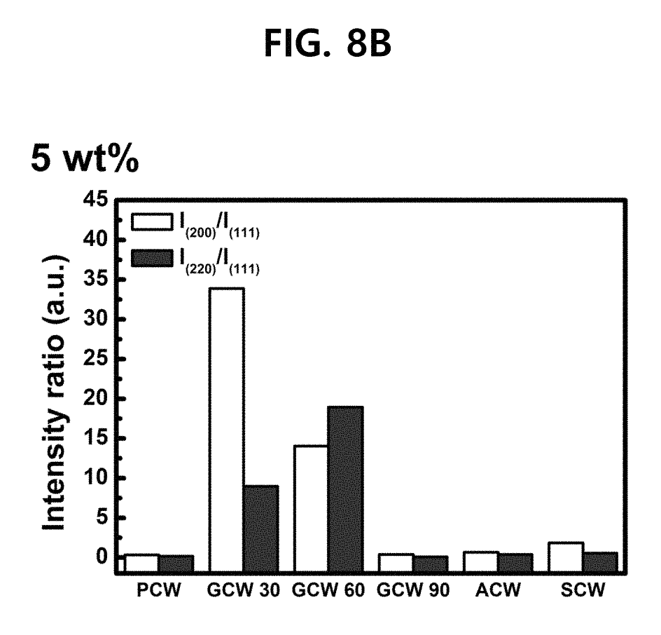

FIGS. 8A and 8B are graphs comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process time in Example 2 of Experiment 1 of the present disclosure and coppers in the Comparative Examples. At this time, the concentration of the polymer solution is each 3.0% (FIG. 8A) and 5.0% (FIG. 8B) based on the weight of a polar solvent. In FIGS. 8A and 8B, Comparative Example 1 (PCW), Example 2 (GCW carbonization time), Comparative Example 2 (ACW), and Comparative Example 3 (SCW) are marked on the X-axis, and the intensity ratios (no unit) are marked on the Y-axis.

As shown in FIGS. 7A, 7B, 8A and 8B, it can be confirmed that regardless of the concentration of the polymer solution, the growth (111) of copper is suppressed and the growth of (200) and (220) is predominant in the graphene/copper composite where the carbonization time is 60 minutes or less, whereas there is a tendency that the growth of (111) is maintained in the graphene/copper composite where the carbonization time is more than 60 minutes.

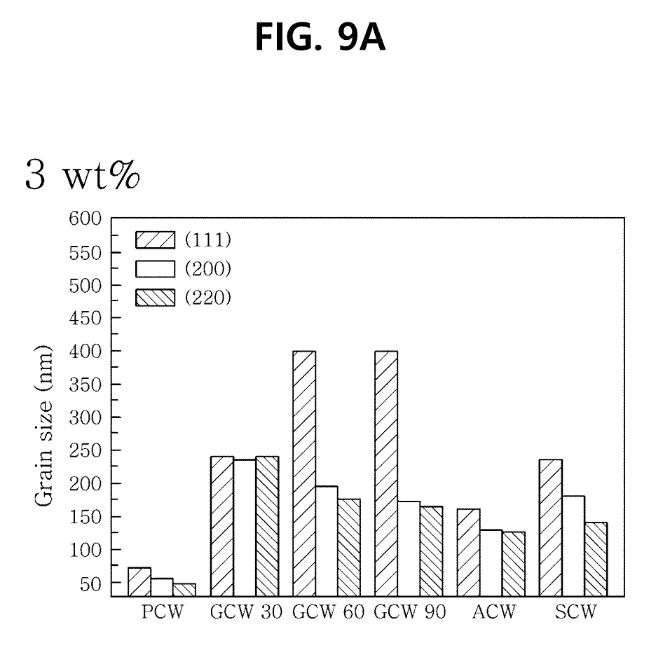

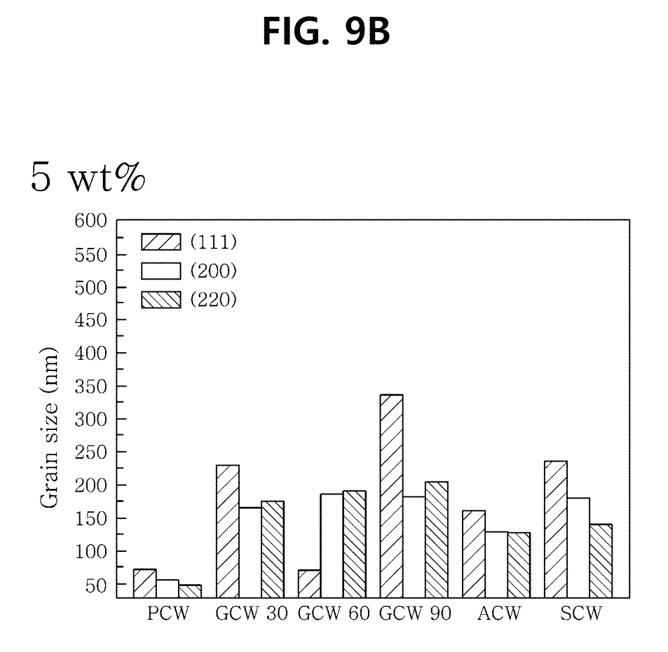

FIGS. 9A and 9B are graphs comparing the grain sizes of each crystal plane by using an XRD graph of a graphene/copper composite prepared according to the carbonization process time in Example 2 of Experiment 1 of the present disclosure and coppers in the Comparative Examples. At this time, the concentration of the polymer solution is each 3.0% (FIG. 9A) and 5.0% (FIG. 9B) based on the weight of the solar solvent. In FIGS. 9A and 9B, Comparative Example 1 (PCW), Example 1 (GCW carbonization time), Comparative Example 2 (ACW), and Comparative Example 3 (SCW) are marked on the X-axis, and the crystal size (unit: nm) is marked on the Y-axis.

As seen in FIGS. 9A and 9B, there is no significant effect on the change in size of the crystal plane of copper according to the carbonization process time.

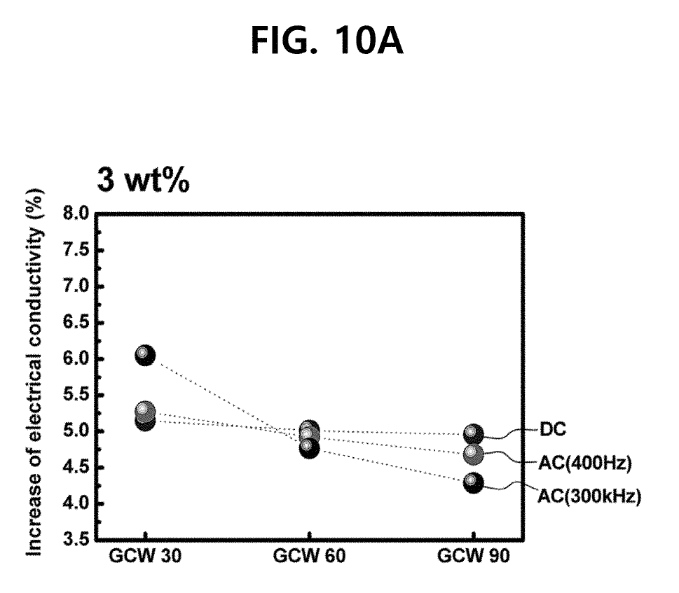

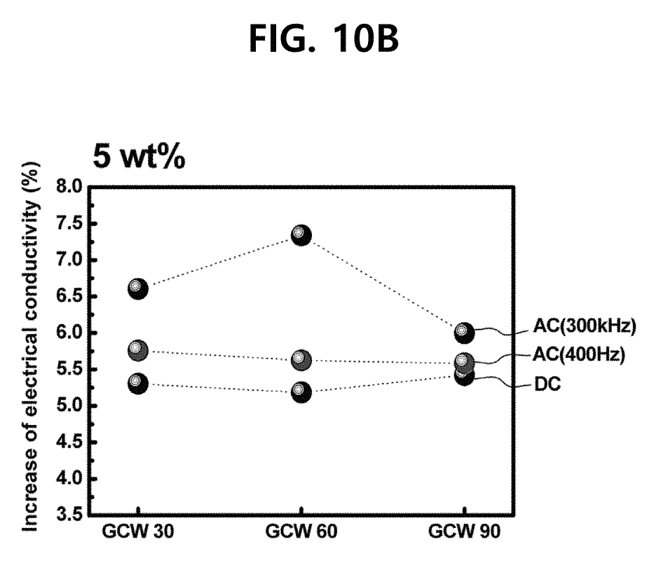

FIGS. 10A and 10B are graphs showing a rate of increase in direct current (DC) and alternating current (AC) conductivities according to the frequency in the graphene/copper composite prepared according to the carbonization process time in Example 2 of Experiment 1 of the present disclosure in comparison with the conductivity of a pure copper wire. At this time, the concentration of the polymer solution is each 3.0% (FIG. 10A) and 5.0% (FIG. 10B) based on the weight of the polar solvent. In FIGS. 10A and 10B, Example 2 (GCW carbonization time) is marked on the X-axis, and the Y-axis indicates a rate of increase in electrical conductivity (unit: %).

In the case where the ratios of XRD intensities in FIGS. 7A, 7B, 8A and 8B are compared with the rate of increase in electrical conductivity, when a heat treatment is performed for the carbonization process time for 60 minutes or less, the growth (111) of copper is suppressed, and the growth of (200) and (220) is predominant. In this regard, it can be confirmed that the rate of increase in electrical conductivity of each graphene/copper composite belong to the maximum value range, and closely affects an improvement in electrical conductivity particularly in a high frequency (300 kHz) region of AC.

For a more detailed description, through two effects of reducing resistance at the grain boundary through the control of the crystal plane toward the single crystal-like copper and providing an excellent electron movement channel by forming graphene on the copper wire (in the present experimental data, a graphene composite formed on the single crystal-like copper wire where the (200) plane of copper is predominant), it is possible to contribute to an improvement in electrical conductivity of the composite wire.

In particular, the alternating current (furthermore, high frequency) has so significant skin effects in which electricity flows through the surface that an improvement effect in electrical conductivity appears to more significantly act than electrical conductivity at direct current and alternating current (low frequency). As described above, in the case of synthesis in a process time of 60 minutes or less, it can be confirmed that the electrical conductivity becomes excellent by the aforementioned two effects (particularly, at the high frequency alternating current) because the graphene composite approaches a single crystal-like copper composite).

### EXAMPLE 3

A graphene/copper composite wire was prepared through the same process, except for the concentration of the polymer solution, the carbonization process time, and gas flow rate in Example 2. The copper wire was coated by using a polymer solution in an amount of 3.0% based on the weight of the polar solvent. Subsequently, a carbonization treatment was performed for 90 minutes by increasing the temperature to 700° C. under a hydrogen:argon gas atmosphere at a flow rate of 5:100, 5:0, and 50:0 sccm.

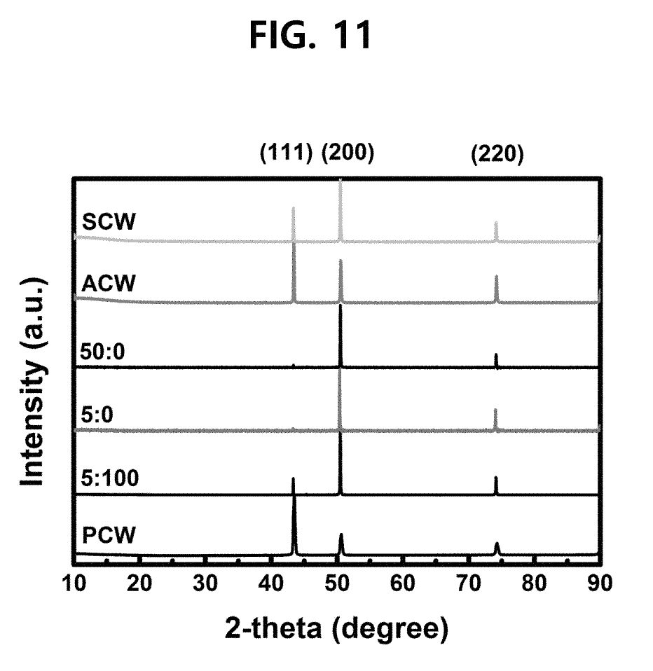

FIG. 11 is an XRD graph of a graphene/copper composite prepared according to the gas flow rate during the carbonization process in Example 3 of Experiment 1 of the present disclosure and coppers in the Comparative Examples. In FIG. 11, an incident angle (unit: degree) of X ray is marked on the X-axis, and the intensities (no unit) of a pure polycrystalline copper wire (PCW) in Comparative Example 1, a graphene/copper composite (hydrogen:argon flow rate (unit: sccm)) for each gas flow rate during the carbonization process (GCW carbonization time) of the carbonization process in Example 3, heat-treated pure polycrystalline copper (ACW) in Comparative Example 2, and pure single crystalline copper (SCW) in Comparative Example 3 are marked on the Y-axis.

It can be confirmed that (111), (200), and (220) of copper were commonly observed.

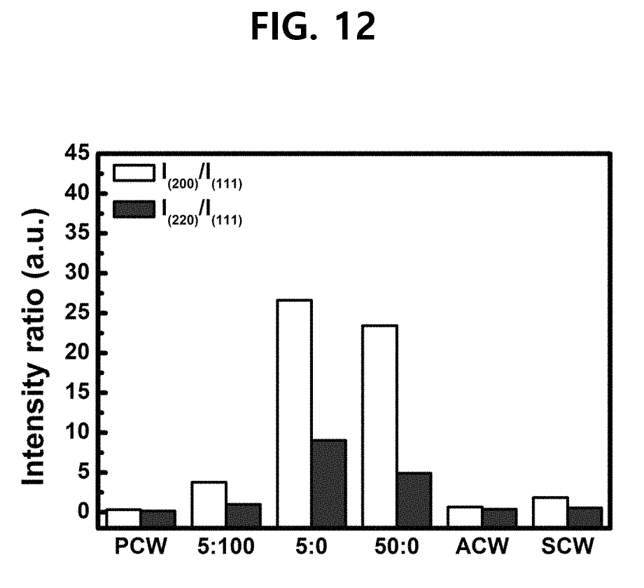

FIG. 12 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the gas flow rate during the carbonization process in Example 3 of Experiment 1 of the present disclosure. In FIG. 12, Comparative Example 1 (PCW), Example 3 (hydrogen:argon flow rate (unit: sccm)), Comparative Example 2 (ACW), and Comparative Example 3 (SCW) are marked on the X-axis, and the intensity ratios (no unit) are marked on the Y-axis.

As shown in FIGS. 11 and 12, it can be confirmed that when a hydrogen gas was flowed alone during the carbonization, the development (111) of copper was suppressed, whereas the growth of (200) was promoted.

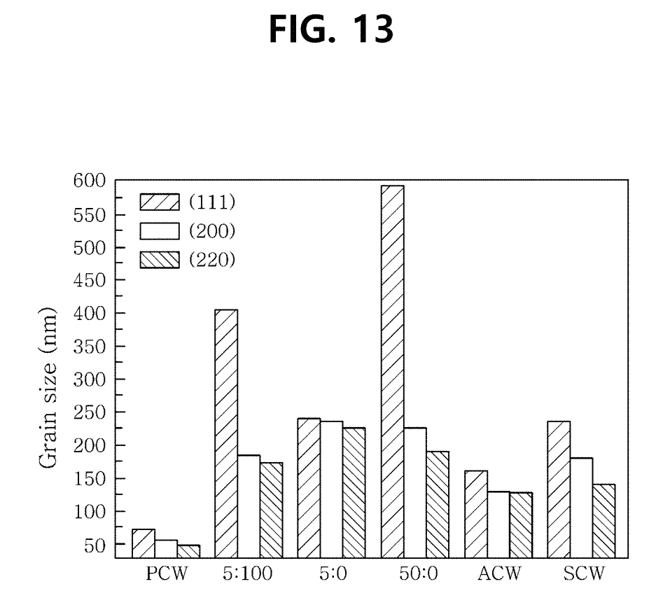

FIG. 13 is a graph comparing the grain sizes of each crystal plane by using an XRD graph of a graphene/copper composite prepared according to the gas flow rate during the carbonization process in Example 3 of Experiment 1 of the present disclosure. In FIG. 13, Comparative Example 1 (PCW), Example 3 (hydrogen:argon flow rate (unit: sccm)), Comparative Example 2 (ACW), and Comparative Example 3 (SCW) are marked on the X-axis, and the crystal sizes (unit: nm) are marked on the Y-axis.

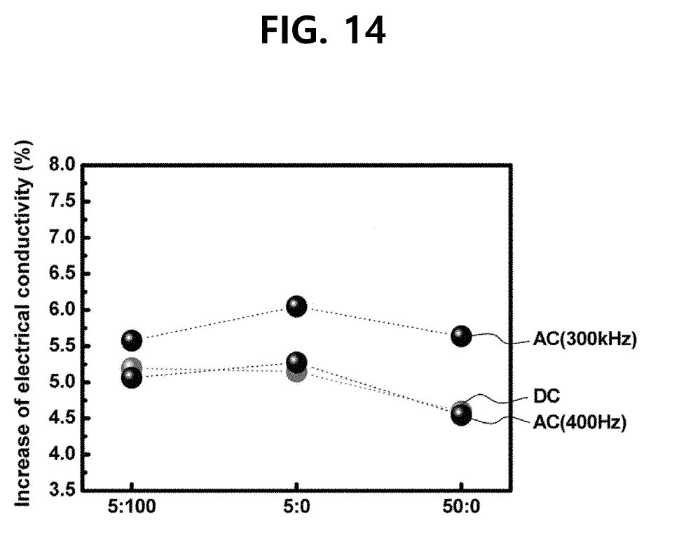

FIG. 14 is a graph showing a rate of increase in direct current (DC) and alternating current (AC) conductivities according to the frequency in the graphene/copper composite prepared according to the gas flow rate during the carbonization process in Example 3 of Experiment 1 of the present disclosure in comparison with the conductivity of a pure copper wire. In FIG. 14, Example 3 (hydrogen:argon flow rate (unit: sccm)) is marked on the X-axis, and the Y-axis indicates a rate of increase in electrical conductivity (unit: %).

When the ratios of XRD intensities in FIGS. 11 and 12 are compared with the rate of increase in electrical conductivity, the growth of (111) of copper is suppressed and the growth of (200) is predominant when hydrogen is used alone at the gas flow rate during the carbonization process, particularly, a small amount of hydrogen is flowed. It can be confirmed that those growths closely affect an improvement in AC electrical conductivity of each graphene/copper composite in a high frequency (300 kHz) region.

For a more detailed description, it can be confirmed that when a composite wire was prepared under synthesis conditions of hydrogen alone rather than a hydrogen/argon mixed gas, the composite wire approaches a single crystal-like composite wire. Further, it can be confirmed that the electrical conductivity and improvement ratio in a high frequency region are larger than those under the comparative conditions (mixed gas). Therefore, during the synthesis under the conditions of only hydrogen, it is determined that the composite wire approaches the single crystal-like composite wire, and contributes to excellent electrical conductivity and improvement at high frequency alternating current.

### EXAMPLE 4

A graphene/copper composite wire was prepared through the same process, except for the gas flow rate and pressure conditions during the carbonization process in Example 3. The gas flow rate during the carbonization process was fixed at 5 sccm, and a heat treatment was performed by changing the carbonization pressure into each of reduced pressure (70 mTorr) (LP) and atmospheric pressure (760 Torr) (AP).

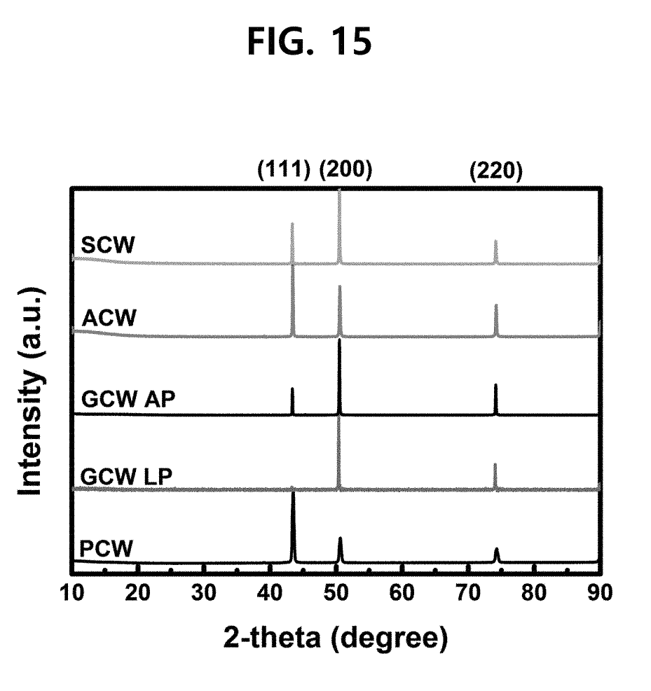

FIG. 15 is an XRD graph of a graphene/copper composite prepared according to the carbonization process pressure in Example 4 of Experiment 1 of the present disclosure. In FIG. 15, an incident angle (unit: degree) of X ray is marked on the X-axis, and the intensities (no unit) of pure polycrystalline copper (PCW) in Comparative Example 1, a graphene/copper composite for each pressure (GCW pressure) of the carbonization process in Example 4, heat-treated pure polycrystalline copper (ACW) in Comparative Example 2, and pure single crystalline copper (SCW) in Comparative Example 3 are marked on the Y-axis.

It can be confirmed that (111), (200), and (220) of copper were commonly observed.

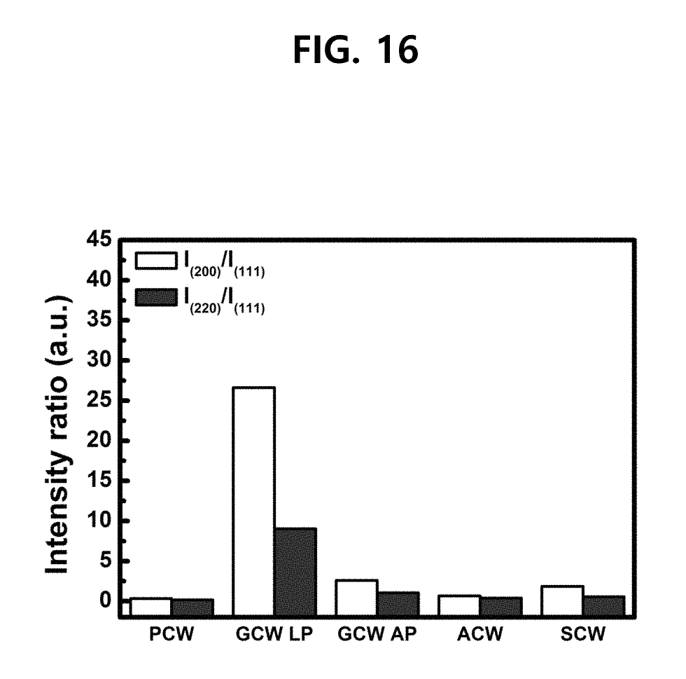

FIG. 16 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared according to the carbonization process pressure in Example 4 of Experiment 1 of the present disclosure. In FIG. 16, Comparative Example 1 (PCW), Example 4 (GCW pressure), Comparative Example 2 (ACW), and Comparative Example 3 (SCW) are marked on the X-axis, and the intensity ratios (no unit) are marked on the Y-axis.

As shown in FIGS. 15 and 16, it can be confirmed that when a carbonization process was performed in a reduced state, the development of (111) of copper was suppressed, whereas the growth of (200) was promoted.

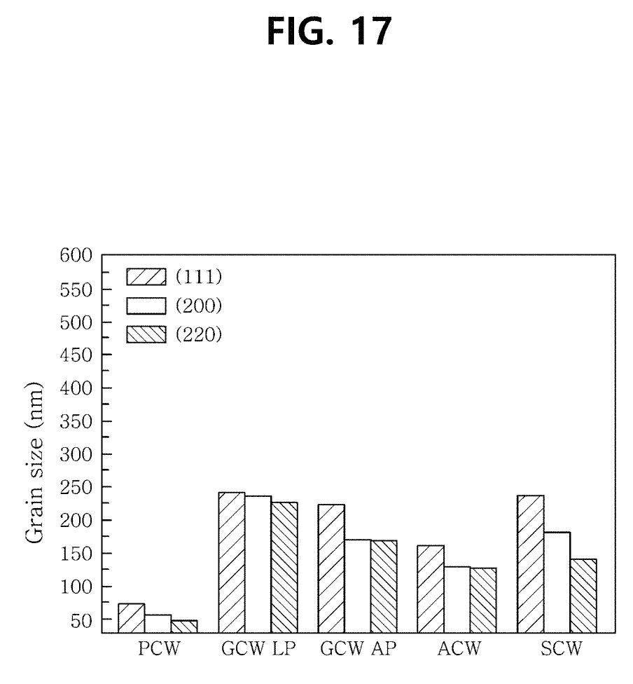

FIG. 17 is a graph comparing the grain sizes of each crystal plane by using an XRD graph of a graphene/copper composite prepared according to the carbonization process pressure in Example 4 of Experiment 1 of the present disclosure. In FIG. 17, Comparative Example 1 (PCW), Example 4 (GCW pressure), Comparative Example 2 (ACW), and Comparative Example 3 (SCW) are marked on the X-axis, and the crystal size (unit: nm) is marked on the Y-axis.

As seen in FIG. 17, there is no significant effect on the change in size of the crystal plane of copper according to the carbonization process pressure.

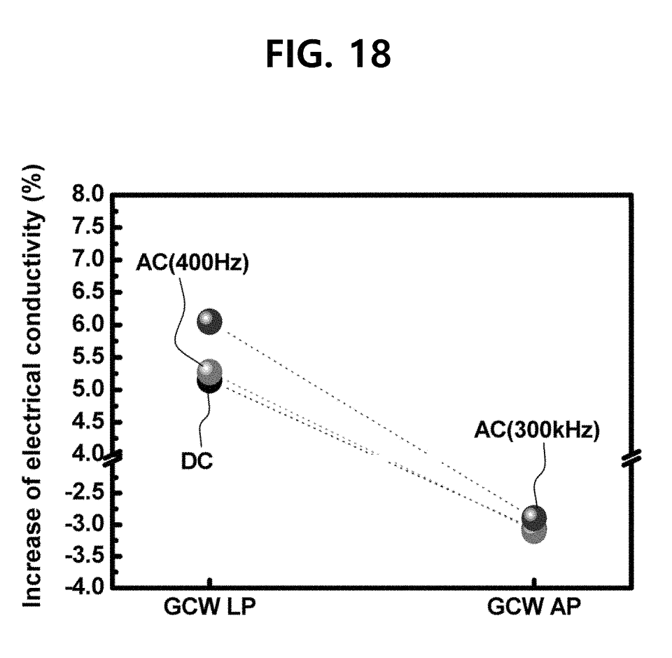

FIG. 18 is a graph showing a rate of increase in direct current (DC) and alternating current (AC) conductivities according to the frequency in the graphene/copper composite prepared according to the carbonization process pressure in Example 4 of Experiment 1 of the present disclosure in comparison with the conductivity of a pure copper wire. In FIG. 18, Example 4 (GCW pressure) is marked on the X-axis, and the Y-axis indicates a rate of increase in electrical conductivity (unit: %).

When the ratios of XRD intensities in FIGS. 15 and 16 are compared with a rate of increase in electrical conductivity, it can be seen that for the carbonization process pressure, the growth of (111) of copper is suppressed and the growth of (200) is predominant regardless of pressure, but particularly when a heat treatment is performed under reduced pressure, the growth of (111) little occurs. Further, it can be confirmed that the graphene/copper composite clearly affects an improvement in electrical conductivity as compared to the electrical conductivity of the graphene/copper composite in an atmospheric pressure state.

For a more detailed description, under the reduced pressure, the composite wire is synthesized in a form more suitable for a single crystal-like composite wire, and thus shows more improved electrical conductivity than that at the high frequency alternating current. As a result, on the data, the composite wire prepared under atmospheric pressure corresponds to the XRD intensity range which can be seen as a single crystal-like metal, but since the intensities of [I(111)] and [I(220)] under reduced pressure are significantly lower than the intensities of two crystal planes at atmospheric pressure, it can be seen that the composite wire formed under reduced pressure rather than under atmospheric pressure are closer to the single crystal-like composite wire.

### EXAMPLE 5

A graphene/copper composite wire was prepared through the same process, except for the concentration of the polymer solution, the carbonization process time, gas flow rate, and presence and absence conditions of a change in temperature in Example 3. The copper wire was coated by using a polymer solution in an amount of 5.0% based on the weight of the polar solvent. Subsequently, a carbonization treatment was performed under a hydrogen gas atmosphere at a flow rate of 5 sccm for 60 minutes. At this time, a heat treatment was performed by varying the carbonization process temperature to 700° C. (absence of a change in temperature) and from 1,000° C. to 700° C. (presence of a change in temperature: carrying out carbonization by increasing the temperature to 1,000° C., and then again decreasing the temperature to 700° C.), respectively.

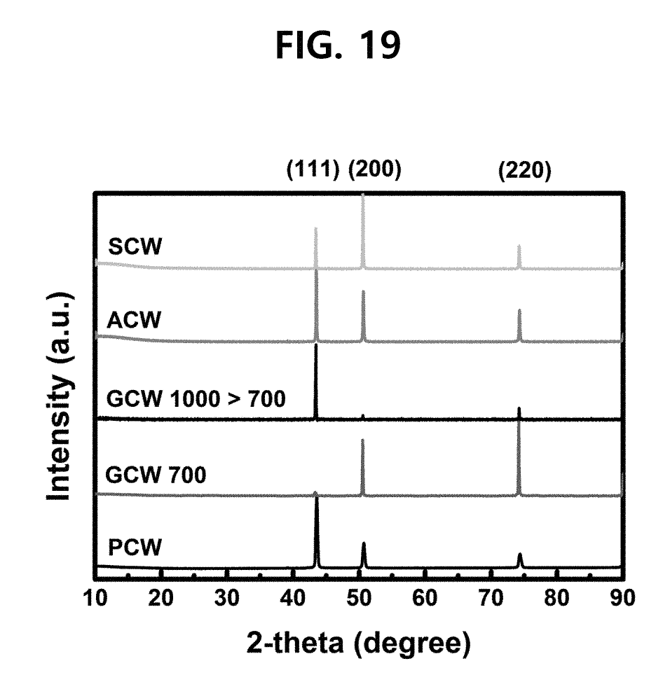

FIG. 19 is an XRD graph of a graphene/copper composite prepared according to the presence and absence of a change in temperature during the carbonization process in Example 5 of Experiment 1 of the present disclosure and the Comparative Examples. In FIG. 19, an incident angle 2 theta (unit: degree) of X ray is marked on the X-axis, and the intensities (no unit) of pure polycrystalline copper (PCW) in Comparative Example 1, a graphene/copper composite in the presence and absence of a change in temperature (change in GCW temperature) during the carbonization process in Example 5, heat-treated pure polycrystalline copper (ACW) in Comparative Example 2, and pure single crystalline copper (SCW) in Comparative Example 3 are marked on the Y-axis.

It can be confirmed that (111), (200), and (220) of copper were commonly observed.

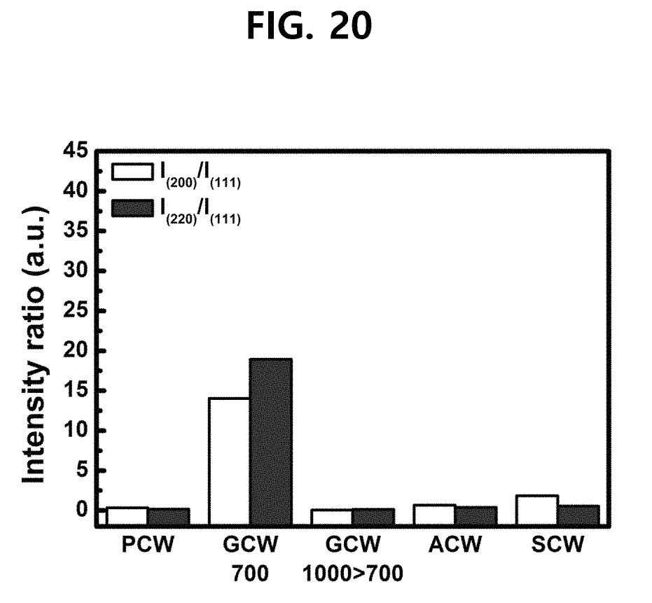

FIG. 20 is a graph comparing the ratios of the intensities of (200) and (220) of copper to the intensity of (111) of copper (represented by I₍₂₀₀₎/I₍₁₁₁₎ and I₍₂₂₀₎/I₍₁₁₁₎, respectively) by using an XRD graph of the graphene/copper composite prepared in the presence and absence of a change in temperature during the carbonization process in Example 5 of Experiment 1 of the present disclosure and coppers in the Comparative Examples. In FIG. 20, Comparative Example 1 (PCW), Example 5 (change in GCW temperature), Comparative Example 2 (ACW), and Comparative Example 3 (SCW) are marked on the X-axis, and the intensity ratios (no unit) are marked on the Y-axis.

As shown in FIGS. 19 and 20, when a change in temperature during the carbonization process is given (lowering the temperature from 1,000° C. to 700° C. in Example 5 of Experiment 1 of the present disclosure), it can be confirmed that a tendency to maximize the growth (111) of copper is exhibited unlike the results in Examples 1 to 4. Unlike the cases in the other Examples, after cooling from 1,000° C. to 700° C., a re-heating process is performed. Since the polymer and the hydrogen gas have been sufficiently reacted on both (111) and (200) crystal planes at 1,000° C., it is contemplated that crystal grains are grown toward the (111) plane, which is a predominant crystal plane of the existing pure copper through a re-heating process at 700° C., and as a result, the polycrystalline metal is finally induced toward the (111) single crystal-like metal.

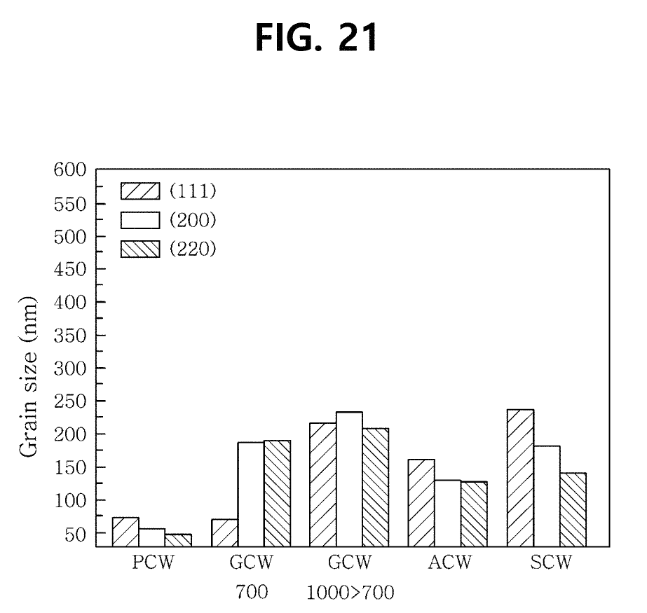

FIG. 21 is a graph comparing the grain sizes of each crystal plane by using an XRD graph of a graphene/copper composite prepared in the presence or absence of a change in temperature during the carbonization process temperature in Example 5 of Experiment 1 of the present disclosure and coppers in the Comparative Examples. In FIG. 21, Comparative Example 1 (PCW), Example 5 (change in GCW temperature), Comparative Example 2 (ACW), and Comparative Example 3 (SCW) are marked on the X-axis, and the crystal size (unit: nm) is marked on the Y-axis.

As seen in FIG. 21, there is no significant effect on the change in size of the copper crystal plane according to the presence and absence of a change in temperature during the carbonization process.

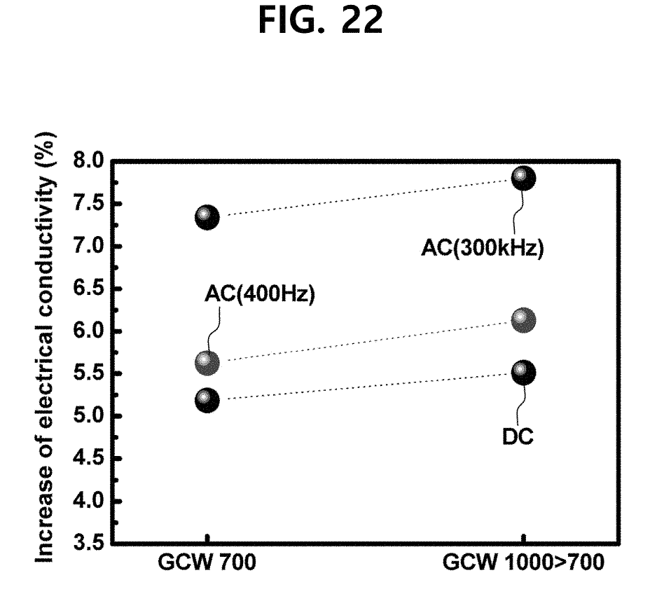

FIG. 22 is a graph showing a rate of increase in direct current (DC) and alternating current (AC) conductivities according to the frequency in the graphene/copper composite prepared according to the change in temperature during the carbonization process in Example 5 of Experiment 1 of the present disclosure in comparison with the conductivity of a pure copper wire. In FIG. 22, Example 5 (change in GCW temperature) is marked on the X-axis, and the Y-axis indicates a rate of increase in electrical conductivity (unit: %).

When the ratios of XRD intensities in FIGS. 21 and 22 are compared with a rate of increase in electrical conductivity, it can be seen that both conditions significantly affect an improvement in AC electrical conductivity in a high-frequency (300 kHz) region. However, it can be confirmed that the case where a change was exceptionally made to the carbonization temperature helps an improvement in electrical conductivity of a graphene/copper composite wire structure when (200) and (220) of copper are suppressed, and the growth of (111) is maximized, in contrast to the XRD trends in the previous Examples 1 to 4.

Unlike the other Examples, even though the composite wire is not a composite wire where the (200) surface is predominant, it is contemplated that as the polycrystalline metal is induced not toward the existing (200) single crystal-like metal through a re-heating of the wire through the cooling procedure during the carbonization, but toward a finally obvious (111) single crystal-like metal, the electrical conductivity value becomes excellent.

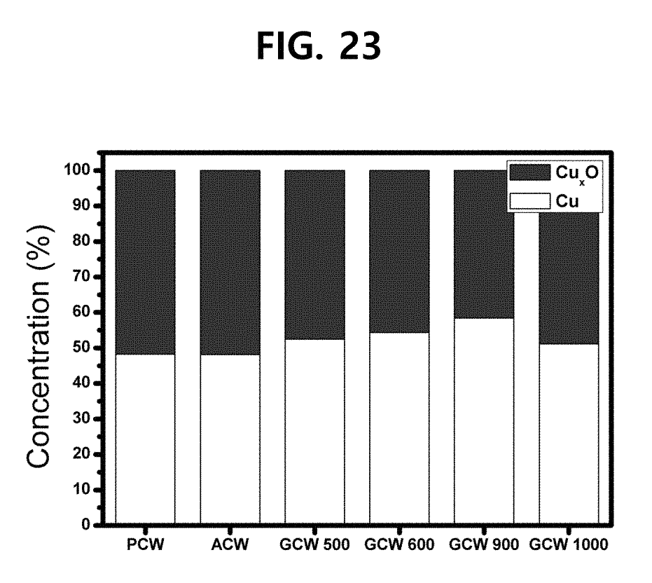

Meanwhile, FIG. 23 shows the ratios of contents of copper and copper oxide of a graphene/copper composite prepared according to the carbonization process temperature in Example 1 and the Comparative Examples. Even though the carbonization temperature has been changed, it can be seen that the ratios of contents of copper and copper oxide are similar to each other.

### EXAMPLE 6

In Example 6 of the present disclosure, the experiment was performed not on a copper wire, but on a copper film.

In order to confirm a change in crystal plane of the copper film and a tendency according to the synthesis temperature, a polycrystalline copper film having a thickness of 25 μm was provided, and a polymer solution having a low concentration of 1.0% based on the weight of a polar solvent was prepared. The polar solvent was N,N-dimethylformamide (DMF), and the polymer is polyacrylonitrile (PAN). The used polyacrylonitrile (PAN) had a molecular weight 150,000 g/mol, and a carbonization yield of 20% to 30%.

As a coating method, a spin coating method was used to coat the entire surface. The coating rate was 500 rpm for 5 seconds, the solution spread over the entire surface of the copper film at 500 rpm for 5 minutes, and then the copper film was coated by evaporating the solvent at a rate of 4,000 rpm for 90 seconds. At this time, the drying time was 1 hours, and the coating thickness was about 20 nm.

Subsequently, a carbonization treatment was performed for 30 minutes while increasing the temperature to a temperature of 500° C., 700° C., and 900° C., respectively under a hydrogen gas atmosphere at a flow rate of 5 sccm. For the pressure during the carbonization, the carbonization treatment was performed under a low pressure of about 70 mTorr. Accordingly, a change in crystal plane of the copper film occurred, and simultaneously, the polymer was formed as a graphene/copper composite film while being carbonized.

### COMPARATIVE EXAMPLE 4

The copper film with a thickness of 25 μm used in Example 6 was provided with a pure copper film (PCF) including no polymer.

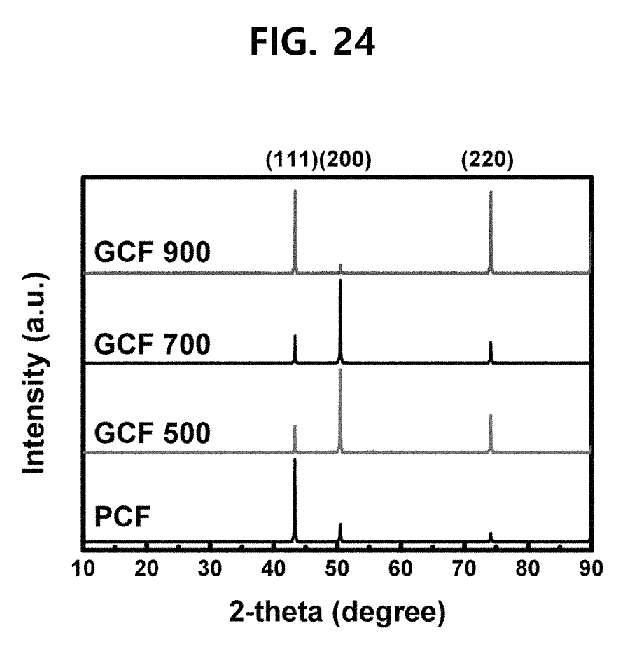

FIG. 24 is an XRD graph of a graphene/copper composite film structure prepared according to the carbonization process temperature in Example 6 of Experiment 1 of the present disclosure and a pure copper film in Comparative Example 4. In FIG. 24, an incident angle (unit: degree) of X ray is marked on the X-axis, and XRD intensities (no unit) of a pure copper film (PCF) in Comparative Example 4 and a graphene/copper composite film structure (GCF carbonization temperature) for each temperature of the carbonization process in Example 6 are marked on the Y-axis.

As shown in FIG. 24, it can be confirmed that (111), (200), and (220) of copper were commonly observed. Further, at a carbonization temperature of 500° C. and 700° C., which are a low temperature, there was observed a tendency that the growth of (111) of copper was suppressed and (200) was developed. In contrast, it can be confirmed that at a temperature of 900° C., the growth of (200) of copper was suppressed and (220) was developed. It can be confirmed that at low temperature, the formation of crystals similar to those of a single crystal copper film were observed through suppression of the (111) plane of copper and growth of the (200) plane of copper, whereas at high temperature, the ratios of intensities of each crystal plane varied, but the (111) plane being a predominant crystal plane of a pure copper film was maintained without being suppressed even after a carbon thin film was formed.

### EXAMPLE 7

A graphene/copper composite film was prepared through the same process, except for the carbonization process temperature and time in Example 6. A carbonization treatment was performed for 15, 30, 60, and 90 minutes, respectively by warming a coated copper film to a temperature of 700° C. using a polymer solution in an amount of 1.0% based on the weight of the polar solvent.

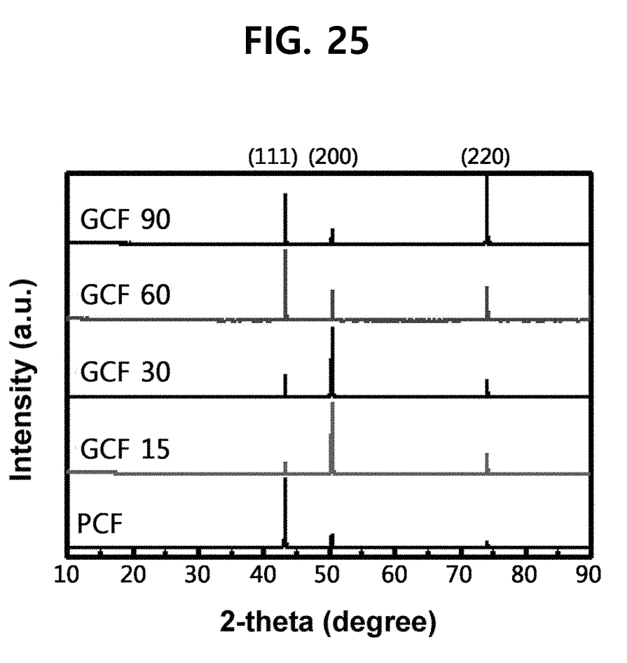

FIG. 25 is an XRD graph of a graphene/copper composite film structure prepared according to the carbonization process time in Example 7 of Experiment 1 of the present disclosure and a pure copper film in Comparative Example 4. In FIG. 25, an incident angle (unit: degree) of X ray is marked on the X-axis, and XRD intensities (no unit) of a pure copper film (PCF) in Comparative Example 4 and a graphene/copper composite film structure (GCF carbonization time) for each time of the carbonization process in Example 7 are marked on the Y-axis.

As shown in FIG. 25, it can be confirmed that (111), (200), and (220) of copper were commonly observed. Further, it can be confirmed that for a carbonization time of 30 minutes or less, there was observed a tendency that the growth of (111) of copper was suppressed and (200) was developed, whereas for a synthesis time of 60 minutes, the growth of (200) of copper was suppressed and (220) was developed. Likewise as previously observed, it can be confirmed that for 30 minutes or less, the formation of crystals similar to those of a single crystal copper film were observed through suppression of the (111) plane of copper and growth of the (200) plane of copper, whereas for 60 minutes or more, the ratios of intensities of each crystal plane varied, but the (111) plane being a predominant crystal plane of a pure copper film was maintained without being suppressed even after a carbon thin film was formed.

[Experiment 2: Aluminum Wire]

### EXAMPLE 1

In order to confirm a change in crystal plane of an aluminum wire according to the gas atmosphere and a tendency, a polycrystalline aluminum wire with a diameter of 0.303 mm and a length of 1.8 m was provided and a polymer solution in an amount of 3.0% based on a weight of a polar solvent was prepared.

The polar solvent was N,N-dimethylformamide (DMF), and the polymer is polyacrylonitrile (PAN). The used polyacrylonitrile (PAN) had a molecular weight 150,000 g/mol, and a carbonization yield of 40% to 50%.

As a coating method, dip coating was used to coat the entire surface similarly to the case of the copper wire. The coating rate was set to be 0.5 m/min, and the drying time was set to be 1 hour. The coating thickness was about 50 nm.

That is, an aluminum wire was immersed in a polymer solution at the rate for several seconds, taken out from the solution, and then dried under air atmosphere. The temperature during the coating and drying was room temperature (25° C.) and the relative humidity was 40% or less.

Subsequently, a carbonization treatment was performed for 30 minutes warming the wire to a temperature of 550° C. under a low pressure of about 70 mTorr. At this time, the gas atmosphere was maintained at a flow rate of 5 sccm in hydrogen alone and 5:100 sccm in a hydrogen/argon mixed gas, respectively.

Accordingly, a change in crystal plane of the aluminum wire occurred, and simultaneously, the polymer was formed as a graphene/copper composite structure while being carbonized.

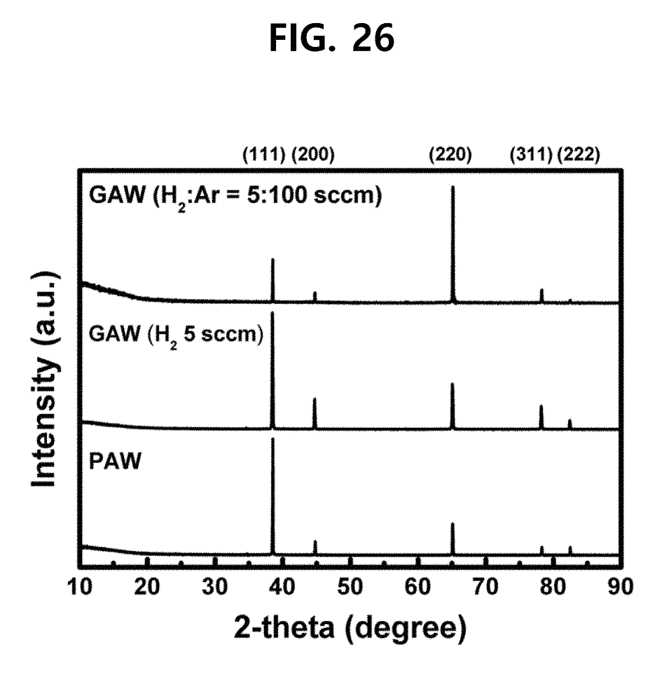

FIG. 26 is an XRD graph of a graphene/aluminum composite wire structure prepared according to the gas atmosphere in Example 1 of Experiment 2 of the present disclosure and the Comparative Examples.

In FIG. 26, an incident angle (unit: degree) of X ray is marked on the X-axis, and XRD intensities (no unit) of a pure aluminum wire (PAW) in Comparative Example 1 and a graphene/aluminum composite wire (GAW) (GAW gas flow rate) for each gas atmosphere in Example 1 are marked on the Y-axis.

It can be confirmed that (111), (200), (220), (311), and (222) of aluminum were commonly observed. The graphene/aluminum composite wire under the atmosphere of a hydrogen gas alone showed an XRD tendency similar to that of an existing pure aluminum wire (PAW).

In contrast, it can be confirmed that in the graphene/aluminum composite wire under the hydrogen/argon mixed gas atmosphere, the growth of (111) of aluminum was suppressed, and (220) was developed.

### EXAMPLE 2

A graphene/aluminum composite wire structure was prepare through the same process, except for the polymer concentration and gas atmosphere in Example 1. The aluminum wire was coated by using a polymer solution in an amount of each 3.0% and 5.0% based on the weight of the polar solvent. Subsequently, a carbonization treatment was performed under a hydrogen flow rate atmosphere of 5 sccm by warming the aluminum wire to a temperature of 550° C.

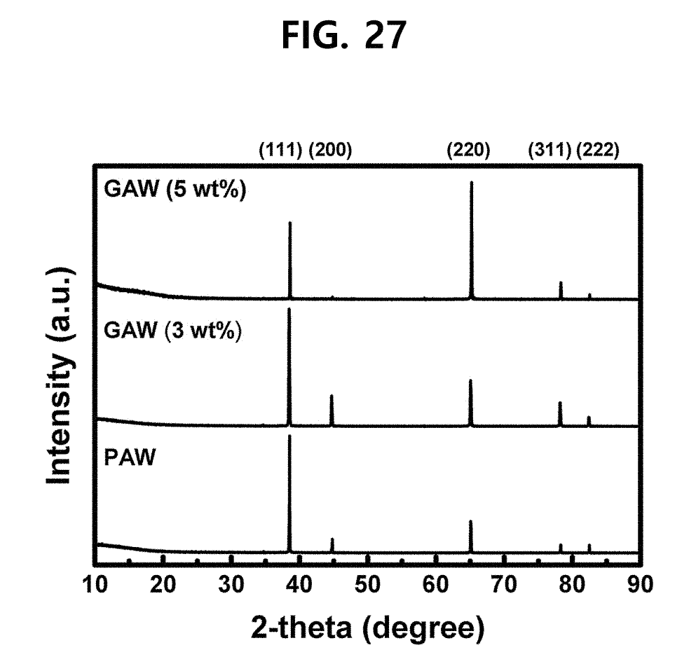

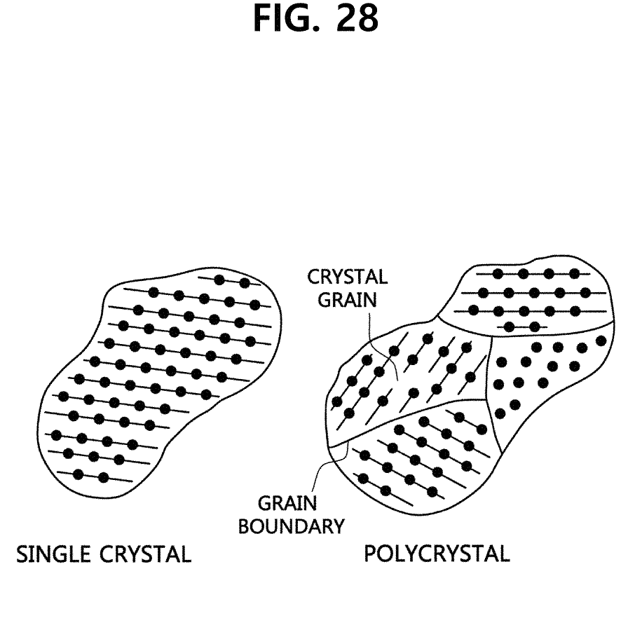

FIG. 27 is an XRD graph of a graphene/aluminum composite prepared according to the polymer concentration in Example 2 of Experiment 2 of the present disclosure and the Comparative Examples.

It can be confirmed that (111), (200), (220), (311), and (222) of aluminum were commonly observed. The graphene/aluminum composite wire coated with a polymer in an amount of 3% based on the weight of the polar solvent showed an XRD tendency similar to that of an existing pure aluminum wire (PAW).

In contrast, it can be confirmed that in the graphene/aluminum composite wire coated with a polymer in an amount of 5% based on the weight of the polar solvent, the growth of (111) of aluminum was suppressed, and (220) was developed.

### COMPARATIVE EXAMPLE 1

The aluminum wire with a diameter of 0.303 mm used in Example 1 was provided with a pure aluminum wire (PAW) including no polymer.

What is claimed is:

1. A metal-carbon material composite where a carbon material is formed on a surface of a polycrystalline metal,
wherein the carbon material is formed through a heat treatment of a polymer on the surface of the metal,
growth of a specific crystal plane of the polycrystalline metal is promoted or suppressed by forming the carbon material, so that a ratio of the crystal plane of the polycrystalline metal is changed differently from a ratio of the crystal plane of the polycrystalline metal prior to the heat treatment.

2. The metal-carbon material composite according to claim 1, wherein when an intensity of a crystal plane having the highest intensity in an XRD graph of the polycrystalline metal after the heat treatment is assumed to be 1, the intensities of the other crystal planes are controlled so as to be 0 or more than 0 and 0.9 or less.

3. The metal-carbon material composite according to claim 1, wherein the metal is one or more metals selected from a group consisting of transition metals comprising one or more of Pt, Ru, Cu, Fe, Ni, Co, Pd, W, Ir, Rh, Sr, Ce, Pr, Nd, Sm, or Re, alloys of the transition metals, non-transition metals comprising one or more of Mg, B, or Al, and alloys of the transition metals.

4. The metal-carbon material composite according to claim 1, wherein the metal has a zero-dimensional, one-dimensional, two-dimensional or three-dimensional form.

5. The metal-carbon material composite according to claim 1, wherein the metal-carbon material composite has a conductivity of 10³ S/cm to 10⁷ S/cm.

6. The metal-carbon material composite according to claim 1, wherein the metal-carbon material composite has an elasticity of 0.1 GPa to 1,000 GPa.

7. The metal-carbon material composite according to claim 1, wherein a maximum allowable current density of the metal-carbon material composite is more than 100% and 10,000% or less based on that of a polycrystalline metal where a carbon material is not formed.

8. A device comprising the metal-carbon material composite of claims 1.

9. The device according to claim 8, wherein the device is an electric wire, an energy device, and an electromagnetic wave shielding material.

10. A method for controlling a crystal plane of a polycrystalline metal, wherein a carbon material is formed on a surface of the polycrystalline metal by performing a heat treatment after providing a polymer on the surface of the polycrystalline metal, and growth of a specific crystal plane of the polycrystalline metal is promoted or suppressed, so that a ratio of the crystal plane of the polycrystalline metal is changed differently from a ratio of the crystal plane of the polycrystalline metal prior to the heat treatment.

11. The method according to claim 10, wherein when an intensity of a crystal plane having the highest intensity in an XRD graph of the polycrystalline metal after the heat treatment is assumed to be 1, the intensities of the other crystal planes are controlled so as to be 0 or more than 0 and 0.9 or less.

12. The method according to claim 10, wherein the method comprises:
a first step of providing the polymer on the surface of a polycrystalline metal; and
a second step of carbonizing the polymer provided on the surface of the polycrystalline metal to the carbon material by subjecting the polycrystalline metal and the provided polymer to the heat treatment.

13. The method according to claim 12, wherein the ratio of the crystal plane is controlled by adjusting one or more of the coating conditions under which the surface of the polycrystalline metal is coated with the polymer and the carbonization conditions through the heat treatment.

14. The method according to claim 12, wherein after the metal is provided with the polymer, a stabilization is further performed.

15. The method according to claim 14, wherein the stabilization comprising a first subjecting the polymer to heat treatment at a temperature of 400° C. or less before the carbonization step, or
inducing a chemical stabilization by using an aqueous strong alkaline solution or a strong alkaline organic solution, or
inducing a stabilization reaction by adding plasma, ion beam, radiation, UV irradiation, or microwave, or
inducing a stabilization by reacting a co-monomer with the polymer to change a structure of polymer chains or chemically cross-linking polymer chains.
